(19) United States
(12) Patent Application Publication
(10) Pub. No.: US 2022/0108847 A1
(43) Pub. Date: Apr. 7, 2022

(54) CONVERSION OF HALIDE PEROVSKITE SURFACES TO INSOLUBLE, WIDE-BANDGAP LEAD OXYSALTS FOR ENHANCED SOLAR CELL STABILITY

(71) Applicants: Nutech Ventures, Lincoln, NE (US); The University of North Carolina at Chapel Hill, Chapel Hill, NC (US)

(72) Inventors: Jinsong Huang, Chapel Hill, NC (US); Shuang Yang, Lincoln, NE (US)

(21) Appl. No.: 17/426,916

(22) PCT Filed: Jan. 24, 2020
(86) PCT No.: PCT/US2020/015067

§ 371 Date: Jul. 29, 2021

Related U.S. Application Data
(60) Provisional application No. 62/798,671, filed on Jan. 30, 2019.

(51) Int. Cl. H01G 9/20; H01L 51/00; C07F 7/24

(52) U.S. Cl. CPC H01G 9/2027; H01L 51/0077; H01L 51/422; H01G 9/2059; C07F 7/24

(57) ABSTRACT

Electronic devices comprising a first layer, said first layer comprising a perovskite material; and a coating layer disposed on a surface of said first layer; wherein said coating layer comprises a coating oxysalt. Also provided herein are perovskite materials comprising: a coating layer on at least a portion of a surface of said perovskite material; wherein said coating layer comprises a coating oxysalt. Further provided herein are methods for forming a coating layer on a surface of a perovskite material comprising steps of: exposing said surface to a fluid having a precursor oxysalt dissolved therein such that said coating layer forms on said surface via a chemical reaction between said perovskite material and said precursor oxysalt; wherein said coating layer comprises a coating oxysalt.

### STATEMENT REGARDING FEDERALLY SPONSORED RESEARCH OR DEVELOPMENT

This invention was made with government support under award number N00014-17-1-2727 awarded by the Office of Naval Research and under award number A9550-16-1-0299 awarded by the Air Force Office of Scientific Research. The government has certain rights in the invention.

### BACKGROUND

Perovskite materials have been demonstrated or envisioned to have applicability and advantageous over other conventional materials in a wide array of applications. Applications that stand to benefit from use of perovskite material include electronic devices, such as photoactive devices including solar cells and light emitting diodes (LEDs). Certain perovskite materials in particular, such as organic-inorganic perovskite materials, provide for solar cells with higher efficiencies than traditional thin film solar cells and with lower material and manufacturing costs than traditional thin film or silicon solar cells. However, various class of perovskite materials suffer from poor stability, such as upon exposure to liquid water or water vapor, which poses significant challenges to further technological and market advancement of devices employing perovskite materials.

Organic-inorganic halide perovskites, for example, have caused unprecedented interests in the field of photovoltaics because of their many unique optoelectronic properties, including strong absorption, long electron-hole diffusion lengths, and solution processability.¹⁻⁵ The power conversion efficiency (PCE) of small size laboratory perovskite solar cells (PSCs) has already reached a certified value of 23.3%, exceeding those of the mainstream thin film solar cells such as CdTe and CIGS solar cells.⁶ However, despite of these great process in efficiency enhancement, PSCs face long-term instability issue under realistic operation conditions, which remains to be a critical hurdle to be overcome before their commercialization.⁷⁻¹⁰

As the key component in PSCs, lead halide perovskites generally suffer from instability under stimuli of heat, oxygen, moisture, light irradiation, and electric field.^{8,11,12} Tailoring the composition, crystallinity and internal strain have been shown to substantially improve the materials' intrinsic stability under different stimuli, but their instability to moisture and oxygen still is still an outstanding issue to be solved.¹³⁻¹⁶ Some reports show that the degradation of perovskite generally initializes from the defective surface and grain boundaries due to the higher reactivity of defect sites, and they are most vulnerable to attack by moisture and oxygen.^{17,18,19} Many organic molecules and polymers have been applied to passivate the surface electronic defects by charge transfer so that the electronic charged defects can be neutralized, while the physical covering of some structural defects using hydrophobic organic materials also enhance the stability of the perovskites.²⁰⁻²² For example, fullerene and its derivatives may be used as passivation layers to enhance device efficiency and reduce current hysteresis, which can accept electrons from the negative-charged Pb-I antisites of PbI₃⁻ or under-coordinated halide ions.²⁰ The surface charged under-coordinated Pb²⁺ sites can be electrically passivated by Lewis base electron donors, such as thiophene, and pyridine via the electric dipole interactions or charge neutralization.²¹ Zwitterions with both negative and positive components are shown to have superior dual passivation effect, which also enhance the stability of unencapsulated perovskite films under ambient conditions.²² However there are limitations relying on these passivation molecules for stability enhancement, because the secondary bonding between these passivation molecules and film defects is too weak to protect the perovskite materials from the attacking of harzards such as moisture and oxygen. In addtion, since not every structural defects are electronic defects, some structure defects which may initialize the film degradation might not be covered by passivation molecules.

Provided herein are perovskite materials, electronic devices, and associated methods, that address these and other challenges.

### SUMMARY

Provided herein are perovskite materials having a protective layer comprising a coating oxysalt thereon. Also provided herein are electronic devices having a perovskite material with a protective oxysalt layer and methods for forming a protective layer comprising a coating oxysalt on a perovskite material. These materials, devices, and methods address significant challenges in the art, such as challenges associated with instability of perovskite materials, which are useful for electronic devices, when exposed to water or humidity. A coating layer comprising a coating oxysalt, according to embodiments disclosed herein, improves the stability of a perovskite material, such as stability against degradation caused by liquid water or water vapor. Electronic devices having a perovskite material and a coating layer comprising a coating oxysalt, according to embodiments disclosed herein, having improved performance metrics and/or extended operational time due to stabilized performance metrics.

In an aspect, an electronic device comprises: a first layer, said first layer comprising a perovskite material; and a coating layer disposed on a surface of said first layer; wherein said coating layer comprises a coating oxysalt. In an embodiment, the coating layer is disposed on at least a portion of the first layer. In an embodiment, the surface of the first layer is an interface between the first layer and the coating layer. In an embodiment, the electronic device further comprises a positive electrode and a negative electrode, wherein each of the positive electrode and the negative electrode is in electronic communication with the perovskite material of the first layer. In an embodiment, the first layer is positioned between the positive electrode and the negative electrode. In an embodiment, the electronic device further comprises an electron transport layer in electronic communication with the perovskite material of the first layer. In an embodiment, the electronic device further comprises a hole transport layer in electronic communication with the perovskite material of the first layer. The terms electron transport layer and hole transport layer are known terms in the field of photoactive devices, such as solar cells and light emitting diodes. In an embodiment, the positive electrode is a cathode. In an embodiment, the negative electrode is an anode. In an embodiment, the negative electrode is a terminal for connection to an external circuit. In an embodiment, the positive electrode is a terminal for connection to an external circuit.

In an aspect, a perovskite material comprises: a coating layer on at least a portion of a surface of said perovskite material; wherein said coating layer comprises a coating oxysalt.

In an aspect, a method for forming a coating layer on a surface of a perovskite material comprises steps of: exposing said surface to a fluid having a precursor oxysalt dissolved therein such that said coating layer forms on said surface via a chemical reaction between said perovskite material and said precursor oxysalt; wherein said coating layer comprises a coating oxysalt.

In any embodiment, the first layer may be an active layer of said electronic device. In any embodiment, the coating oxysalt may be characterized by a chemical formula comprising a metal element. In any embodiment, the perovskite material may be characterized by a chemical formula comprising said metal element. In any embodiment, the coating oxysalt may be characterized by a chemical formula comprising a metal element and wherein said perovskite material may be characterized by a chemical formula comprising said metal element. In any embodiment, the coating oxysalt may be characterized by a chemical formula comprising an inorganic anion. In some embodiments, a precursor oxysalt is characterized by a chemical formula comprising an organic cation and/or a cation that is H⁺. In some embodiments, a precursor oxysalt is an oxyacid. In some embodiments, a coating oxysalt is characterized by a chemical formula comprising an inorganic cation. In some embodiments, a coating oxysalt is characterized by a chemical formula that does not comprise an organic cation. In some embodiments, a coating oxysalt is characterized by a chemical formula that does not comprise a cation that is H⁺. In some embodiments, a coating oxysalt is an inorganic oxysalt, wherein the coating oxysalt is characterized by a chemical formula that does not comprise an organic anion nor an organic cation. In some embodiments, a coating oxysalt is not an oxyacid. In any embodiment, the coating oxysalt may be characterized by a chemical formula comprising at least one anion selected from the group consisting of SO₄²⁻, SO₃²⁻, SO₆⁶⁻, PO₄³⁻, PO₅⁵⁻, PO₃⁻, CO₃²⁻, CO₄⁴⁻, C₂O4²⁻, OH⁻, ClO⁻, ClO₂, ClO₃⁻, ClO₄⁻, NO₂⁻, NO₃⁻, BO₂⁻, BO₃³⁻, AsO₄³⁻, MnO₄⁻, SeO₄²⁻, TeO₆⁶⁻, BrO⁻, BrO₄⁻, IO₆⁶⁻, SiO₄⁴⁻, Cr₂O₇²⁻, and any combination thereof. In any embodiment, the coating oxysalt may be characterized by a chemical formula comprising at least one cation selected from the group consisting of Pb, Sn, Cd, Bi, Sb, Fe, Ge, Mn, Mo, Ta, Ag and any combination thereof. In any embodiment, the coating oxysalt comprises Pb SO₄, Pb SO₃, Pb₃SO₆, Pb₃(PO₄)₂, Pb₅(PO₅)₂, Pb(PO₃)₂, PbCO₃, Pb₂CO₄, PbC₂O₄, Pb(OH)₂, Pb(ClO)₂, Pb(ClO₂)₂, Pb(ClO₃)₂, Pb(ClO₄)₂, Pb(NO₂)₂, Pb(NO₃)₂, Pb(B02)₂, Pb₃(BO₃)₂, Pb₃(AsO₄)₂, Pb(MnO₄)₂, PbSeO₄, Pb₃TeO₆, Pb(BrO)₂, Pb(BrO₄)₂, Pb(IO)₂, Pb(IO₄)₂, Pb₃IO_{6 ,}Pb₂SiO₄, PbCr₂O₇, and any combination thereof. In any embodiment, the perovskite material may be an inorganic perovskite material, and an organic-inorganic perovskite material, or a combination thereof. In some embodiment, the perovskite material is an organic-inorganic perovskite material. In some embodiment, the perovskite material is an inorganic perovskite material. In any embodiment, the perovskite material may be characterized by a chemical formula comprising at least two chemical species selected from the group consisting of Pb, Sn, Sb, Fe, Ge, Mn, Mo, Ta, Ag, Na, K, Ru, Cs, formamidinium (“FA”), methylammonium (“MA”), ethylammonium, propylammonium, butylammonium, amylammonium, hexylammonium, heptylammonium, octylammonium, oleylammonium, formamidinium, dodecylammonium, phenylethylammonium, benzylammonium, ethylenediammonium, tetramethylammonium, tetraethylammonium, tetrabutylammonium, hexadecyl trimethyl ammonium, and ethanediammonium, and at least one chemical species selected from the group consisting of I, Br, Cl, F, COO, BF₃, and SCN. In any embodiment, the perovskite material may be characterized by a chemical formula comprising Pb and wherein said coating oxysalt may be characterized by a chemical formula comprising Pb. In some embodiments, the perovskite material comprises Cs, FA, MA, Pb, I, and Br.

In any embodiment of the electronic devices disclosed herein, the first layer may be a thin film characterized by a thickness selected from the range of 2 nm to 10 μm. In any embodiment of the perovskite materials and methods disclosed herein, the perovskite material be in the form of a thin film characterized by a thickness selected from the range of 2 nm to 10 μm. In some embodiments, the thin film has a thickness selected from the range of 2 nm to 1 μm, preferably for some applications 10 nm to 800 nm, preferably for some applications 100 nm to 700 nm.

In any embodiment of the electronic devices disclosed herein, the electronic device is a photoactive device. In any embodiment of the electronic devices disclosed herein, the electronic device is selected from the group consisting of a solar cell, a light emitting diode, a photodiode, a photoelectrochemical cell, a photoresistor, phototransistor, photomultiplier, photoelectric cell, an electrochromic cell, a radiation detector, an X-ray detector, and a gamma-ray detector.

In any embodiment, the coating layer may be a semiconductor characterized by a band gap selected from the range of 1.6 eV to 5.0 eV, or preferably for some applications 1.6 eV to 8.5 eV. In any embodiment, the coating oxysalt may be characterized by a solubility in water of less than 0.07 g per 100 mL of water at 20° C. In some embodiments, the coating oxysalt is characterized by a solubility in water of less than 100 g, optionally less than 10 g, optionally less than 1 g, preferably for some applications less than 0.16 g, more preferably for some applications less than 0.1 g, more preferably for some applications less than 0.07 g, more preferably for some applications less than 0.02 g, more preferably for some applications less than 0.007 g, and still more preferably for some applications less than 0.005 g, per 100 mL of water at 20° C. In some embodiments, the coating layer, which comprises a coating oxysalt, is a barrier or protection layer that decreases the amount and/or rate of exposure of the perovskite material to water (as liquid, vapor, or otherwise), oxygen or other harmful species in air. Harmful species refer to species that may react with and degrade the perovskite material and/or other layers of a device in such a way as to negatively impact performance of the perovskite material or the device. Solubility of the coating oxysalt in water is a parameter that may be relevant to the degree of protection provided by the coating layer to the perovskite against degradation via exposure to water (as liquid, vapor, or otherwise), oxygen or other harmful species in air In some embodiments, the coating layer, which comprises a coating oxysalt, is a barrier or protection layer that decreases the amount and/or rate of exposure of the perovskite material to oxygen from the atmosphere and/or reactive ion migration from other layers in the device.

In any embodiment, the coating oxysalt may be formed via a chemical reaction of a precursor oxysalt with said perovskite material. In any embodiment, the coating layer may be formed via a chemical reaction of a precursor oxysalt with said perovskite material. Generally, wherein a coating oxysalt is formed via a chemical reaction of a precursor oxysalt with a perovskite material, the coating oxysalt is different from the precursor oxysalt. For example, a precursor oxysalt may substantially comprise (C₈H₁₆NH₃)₂SO₄ and a corresponding coating oxysalt may substantially comprise PbSO₄.

In any embodiment, the an absorbance loss at 740 nm of said perovskite material in said first layer, or portion thereof having the coating layer thereon, is less than 20% after at least 500 hours of exposure to ambient air under an illumination equivalent to 1 sun. In any embodiment, an absorbance loss at 740 nm of said perovskite material in said first layer, or portion thereof having the coating layer thereon, is less than 50%, preferably for some applications less than 30%, preferably for some applications less than 20%, and more preferably for some applications less than 17%, after at least 100 hours, preferably for some applications at least 200 hours, and more preferably for some applications at least 500 hours of exposure to ambient air under an illumination equivalent to 1 sun. In any embodiment, the absorbance loss at 740 nm of said perovskite material, or portion thereof having the coating layer thereon, is less than 50%, preferably for some applications less than 30%, preferably for some applications less than 20%, and more preferably for some applications less than 17%, after at least 100 hours, preferably for some applications at least 200 hours, and more preferably for some applications at least 500 hours of exposure to ambient air under an illumination equivalent to 1 sun. In any embodiment, the perovskite material, or portion thereof having the coating layer thereon, may be substantially black after at least 1 second, preferably for some applications at least 20 seconds, preferably for some applications at least 60 seconds, of immersion or direct physical contact in liquid water.

In any embodiment of the electronic devices disclosed herein, a density of electronic trap density of states (“tDOS”) of said first layer, or portion thereof having the coating layer thereon, at 0.35-0.42 eV is at least 10 times less than the tDOS at 0.35-0.42 eV of an equivalent first layer that is free of said coating layer. In any embodiment, a density of electronic trap density of states (“tDOS”) of the perovskite material, or portion thereof having the coating layer thereon, at 0.35-0.42 eV is at least 10 times less than the tDOS at 0.35-0.42 eV of an equivalent first layer that is free of said coating layer.

In any embodiment of the electronic devices disclosed herein, the first layer, or portion thereof having the coating layer thereon, may be characterized by a charge-recombination lifetime under illumination equivalent to 1 sun of at least 0.4 μs. In any embodiment of the electronic devices disclosed herein, the first layer, or portion thereof having the coating layer thereon, may be characterized by a charge-recombination lifetime under illumination equivalent to 1 sun of at least 0.4 μs, preferably for some applications at least 0.4 μs. In any embodiment, the perovskite material, or portion thereof having the coating layer thereon, may be characterized by a charge-recombination lifetime under illumination equivalent to 1 sun of at least 0.4 μs, preferably for some applications at least 0.5 μs.

In any embodiment of the perovskite materials or methods disclosed herein, the perovskite material may be in the form of a single crystal, a thin film, a nanomaterial, or a combination of these. In an embodiment, a nanomaterial refers to nanocrystal(s), quantum dot(s), nanowire(s), nanorod(s), nanopyramid(s), or a combination of these.

In any embodiment of the methods disclosed herein, the fluid may be a liquid solution comprising a solvent and said precursor oxysalt. In any embodiment of the methods disclosed herein, the solvent may be an orthogonal solvent. In any embodiment of the methods disclosed herein, the solvent may comprise a compound selected from the group consisting of isopropanol, toluene, chlorobenzene, benzene, chloroform, dichloromethane, trichloromethane, ethanol, methanol, butanol, pentanol, hexanol, heptanol, ethyl acetate, methyl acetate, ethyl formate, methyl formate, 1,2-dichlorobenzene, 1,4-dioxane, butanone, carbon disulfide, carbon tetrachloride, cyclohexanone, diglyme, heptane, p-xylene, tetrahydrofuran, and any combination thereof.

In any embodiment of the methods disclosed herein, the chemical reaction occurs for a time selected from the range of 0.001 seconds to 1800 seconds during the step of exposing. In any embodiment of the methods disclosed herein, the chemical reaction occurs for a time selected from the range of 5 seconds to 1800 seconds during the step of exposing. In any embodiment of the methods disclosed herein, the chemical reaction occurs for a time selected from the range of 5 seconds to 60 seconds during the step of exposing. In any embodiment of the methods disclosed herein, a temperature of said fluid is selected from the range of −40° C. to 100° C., preferably for some applications from the range of 0° C. to 100° C., during said step of exposing. In any embodiment of the methods disclosed herein, a temperature of said perovskite material is selected from the range of 0° C. to 200° C. during said step of exposing.

In any embodiment of the electronic devices disclosed herein, the electronic device is a solar cell; and said solar cell may be characterized by a photocurrent hysteresis substantially equivalent to 0, when exposed to illumination equivalent to 1 sun. In any embodiment of the electronic devices disclosed herein, the electronic device is a solar cell; and said solar cell may be characterized by an average stabilized power conversion efficiency (“PCE”) of at least 21%. In any embodiment of the electronic devices disclosed herein, the electronic device is a solar cell; and said solar cell may be characterized by an average stabilized power conversion efficiency (“PCE”) substantially equivalent to 21%. In any embodiment of the electronic devices disclosed herein, the electronic device is a solar cell; and said solar cell may be characterized by less than 5% loss in PCE after at least 1200 hours of continuous illumination in ambient air while the solar cell has a resistance load applied thereto. In an embodiment, the resistance load corresponds to a maximum power point (“MPP”) of the solar cell before the 1200 hours of continuous illumination. In any embodiment the perovskite material, or a layer thereof having the coating layer thereon, does not exhibit an electronic-to-ionic conductivity transition at a temperature of less than or equal to 300 K, under illumination or in darkness, when determined using a temperature-dependent electrical conductivity measurement technique.

In some embodiments, the first layer of the electronic device is positioned above a substrate. In some embodiments, the first layer of the electronic device is disposed directly or indirectly on a substrate.

Disclosed herein are electronic devices having any combination of the embodiments of electronic devices and perovskite materials described herein. Also disclosed herein are methods comprising any combination of embodiments of the methods, perovskite materials, and/or electronic devices described herein. Also disclosed herein are perovskite materials having any combination of the embodiments of electronic devices and perovskite materials described herein.

Without wishing to be bound by any particular theory, there may be discussion herein of beliefs or understandings of underlying principles relating to the devices and methods disclosed herein. It is recognized that regardless of the ultimate correctness of any mechanistic explanation or hypothesis, an embodiment of the invention can nonetheless be operative and useful.

### BRIEF DESCRIPTION OF THE DRAWINGS

FIG. 1. Organohalide lead perovskite stabilized by a sulfate surface layer. (Panel a) Schematic illustration of protection of perovskites by in-situ formation of a sulfated top layer on the perovskite surface. Scanning electron microscopy (SEM) images of the control (Panel b) and sulfate-treated (Panel c) perovskite films deposited on ITO glass. (Panel d) FT-IR measurement of perovskite powder with or without Pb SO₄ layer. The XPS spectra of Pb 4f (Panel e), I 3d (Panel f) and S 2p (Panel g) for the perovskite films deposited on ITO glass.

FIG. 2. Enhanced water resistance by sulfate top layer. (Panel a) MAPbI₃ single crystals without and with sulfated top layers dipped into water with different time intervals. (Panel b) Normalized absorbance decay at 740 nm for perovskite films sandwiched between PTAA and PCBM layers under simulated AM 1.5G irradiation (100 mW cm⁻²) in ambient air.

FIG. 3. Suppressed ion migration in sulfate-treated perovskites. Temperature-dependent conductivity of the PTAA/CsFAMA perovskite/PCBM films without (Panel a) and with (Panel b) methylammonium sulfate treatment, and MAPbI₃ single crystal without (Panel c) and with (Panel d) methylammonium sulfate treatment. The light intensity is 10 mW cm⁻² for all measurements.

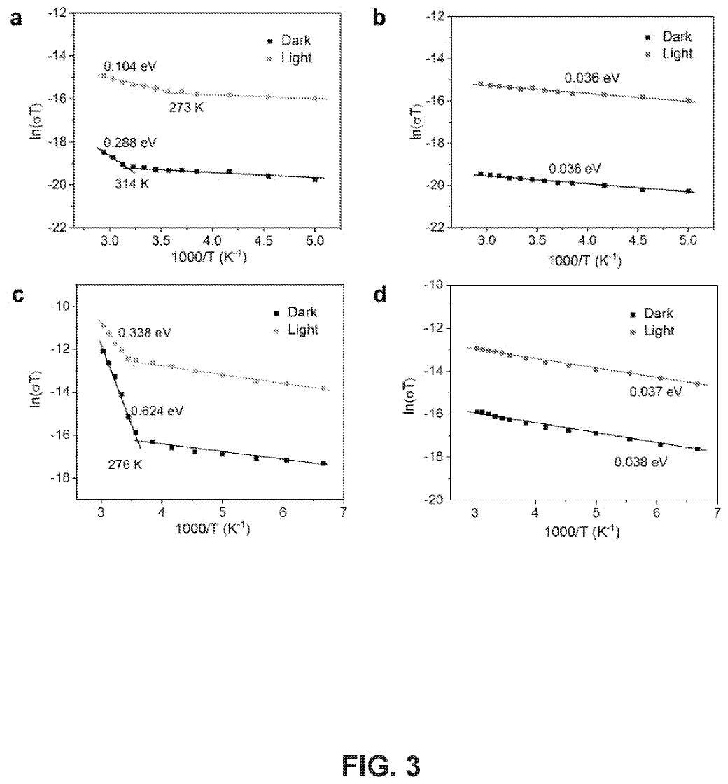

FIG. 4. Performance of perovskite solar cells. (Panel a) J-V curves of perovskite solar cells based on perovskite films treated with different precursor solution. (Panel b) J-V curves of the champion sulfate-treated device measured in both reverse (blue) and forward (red) scanning directions. All the J-V curves were measured under 100 mW cm' simulated AM 1.5G sunlight. (Panel c) Statistical distribution of Voc for the devices with (blue) or without (orange) sulfated top layers. (Panel d) Trap density of states obtained by thermal admittance spectroscopy for the devices with (blue) or without (orange) sulfated top layers. The vertical dashed lines define trap bands with different trap energy depths, shallow trap states (band 1, 0.35-0.40 eV), deep trap states (band 2 and band 3, >0.4 eV). (Panel e) Steady-state PL spectra and (Panel f) time-resolved PL decay of perovskite films with and without a sulfated layer on glass substrates. The fluence and the excitation density were 2.0 nJ cm' and 4.07×10¹⁴ cm⁻³, respectively. (Panel f) TPV decay curves of the photovoltaic devices with and without sulfated top layers.

FIG. 5. Long-term stability test of encapsulated solar cell devices based on control and sulfate-treated CsFAMA perovskite active layer. Devices were measured under a constant AM 1.5 G illumination in ambient condition (relative humidity ˜60±10%) without any ultraviolet filter.

FIG. 6. XRD patterns of perovskite films reacted with octylammonium sulfate precursor solution for 30 min. Diffraction peaks of the products could be ascribed to the formation of anglesite Pb SO_{4.} Inset is the photography of the as-resulted Pb SO₄ film.

FIG. 7. XRD patterns of films treated with octylammonium phosphate precursor solution for 60 min. Diffraction peaks of the products can be ascribed to Pb₃(PO₄)_{2.} Inset is the photography of the as-resulted Pb₃(PO₄)₂ film.

FIG. 8. FT-IR spectrum of Pb SO₄ powder. The FT-IR peaks at 964, 1040 and 1145 cm⁻² represent the symmetric stretching (v₁) and asymmetric stretching (v3) of sulfate ions, respectively.

FIG. 9. UV-vis absorption spectra of perovskite films sandwiched between PTAA and PCBM layers under light illumination (˜70 mW cm⁻²) recorded at different time intervals. Curves from top to bottom are corresponding to that from 0 to 21 days.

FIG. 10. Photographs of different perovskite films before and after light irradiation for 4 days. All films were irradiated under an AM1.5 70 mW cm⁻² solar simulator in air. OAI is octylammonium iodide, MAS is methylammonium sulfate, and OAS is octylammonium sulfate.

FIG. 11. UV-vis absorption spectra of perovskite films under light illumination (˜70 mW cm⁻²) and dry air recorded at different time intervals.

FIG. 12. Surface SEM image of perovskite films without (left) and with a sulfate layer (right) aged under 70 mW cm⁻³ irradiation for 24 hours in air.

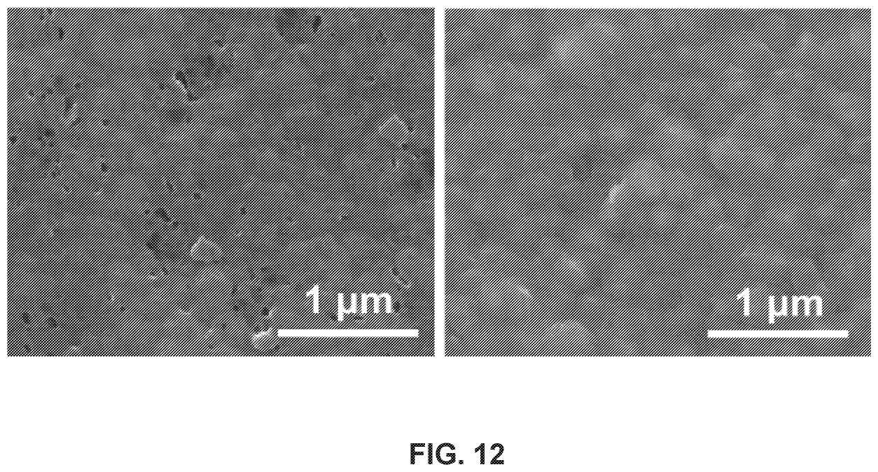

FIG. 13. Comparison of J-V metrics for 25 independent solar cells based on control and sulfate perovskite films.

FIG. 14. EQE spectra of the device based on sulfate perovskite layer. The integrated Jsc is 22.3 mA cm⁻².

FIG. 15. Steady-state measurement of the photocurrent and PCE of the champion device based on sulfate perovskite layer held at maximum power point (MPP) voltage of 0.99 V.

FIG. 16. J-V curves of the champion phosphate device measured in reverse (blue) and forward (red) scanning directions

FIG. 17. Steady-state PL spectra of control and sulfate perovskite films.

FIG. 18. TPV spectra of photovoltaic devices with and without phosphate layer.

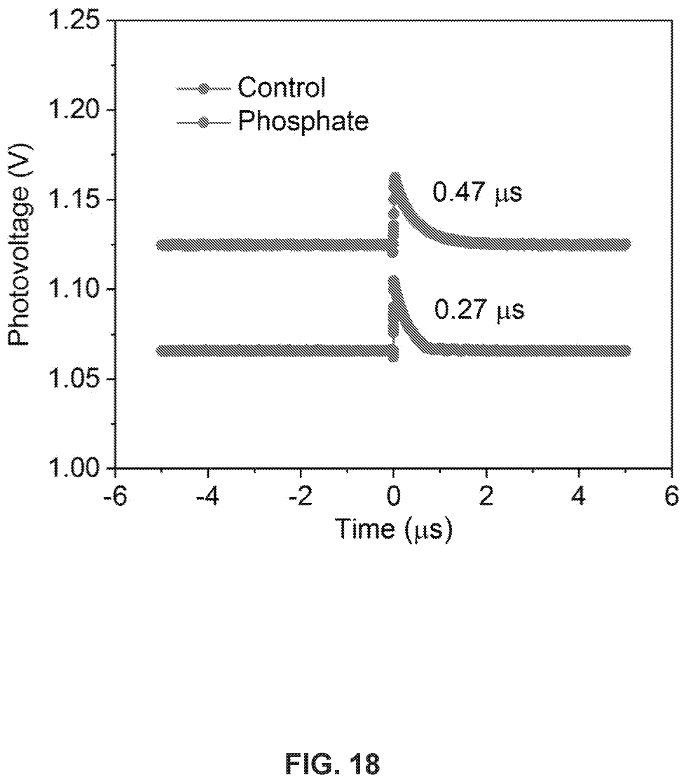

FIG. 19A. A schematic of a perovskite material comprising a coating layer on a surface of the perovskite material, according to certain embodiments. FIG. 19B. A schematic of a perovskite material comprising a coating layer on each of a plurality of surface of the perovskite material, according to certain embodiments.

FIG. 20. A schematic of an electronic device, according to certain embodiments.

FIG. 21. A flowchart representing a method for forming a coating layer on a surface of a perovskite material, according to certain embodiments.

FIG. 22. Each of panels A and B of FIG. 22 shows an embodiment of an electronic device. The electronic devices of panels A and B differ in the configuration of the device layers.

FIG. 23. Plots of short circuit current density (Jsc), open circuit voltage (Voc), fill factor (FF), and power conversion efficiency (PCE) versus time showing long-term performance stability corresponding to photovoltaic devices comprising an oxysalt coating layer according to certain embodiments.

### STATEMENTS REGARDING CHEMICAL COMPOUNDS AND NOMENCLATURE

In general, the terms and phrases used herein have their art-recognized meaning, which can be found by reference to standard texts, journal references and contexts known to those skilled in the art. The following definitions are provided to clarify their specific use in the context of the invention.

As used herein, the term “oxysalt” refers to a chemical compound or specie having at least one cation and at least one anion associated with each other via ionic bonding, wherein at least one anion includes an oxygen atom (0) in its chemical formula. In an embodiment, an oxysalt may be characterized as an oxyacid if at least one anion thereof is protonated (e.g., if at least one cation is H⁺). As used herein, an oxysalt may be a precursor oxysalt, such that chemical reaction between a perovskite material and the precursor oxysalt may result in formation of a coating oxysalt. In some embodiments, a precursor oxysalt comprises an organic cation and/or a cation that is H⁺. In some embodiments, a precursor oxysalt is an oxyacid. In some embodiments, a coating oxysalt comprises an inorganic cation. In some embodiments, a coating oxysalt does not comprise an organic cation. In some embodiments, a coating oxysalt does not comprise a cation that is H⁺. In some embodiments, a coating oxysalt is an inorganic oxysalt, wherein the coating oxysalt does not comprise an organic anion nor an organic cation. In some embodiments, a coating oxysalt is not an oxyacid. An inorganic anion or cation refers to an anion or cation, respectively, which does not comprise C in its chemical formula. An organic anion or cation refers to an anion or cation, respectively, which does comprise C in its chemical formula. Exemplary cations of a precursor oxysalt include, but are not limited to, H⁺, ammonium, methylammonium, octylammonium, and any combination of these. Exemplary anions of a precursor oxysalt include, but are not limited to, SO₄²⁻, PO₄³⁻, OH⁻, CO₃²⁻, ClO₄⁻, and any combination of these. Exemplary precursor oxysalts include, but are not limited to, (C₈H₁₆NH₃)₂SO₄, (C₈H₁₆NH₃)₃PO₄, (C₈H₁₆NH₃)₂CO₃, C₈H₁₆NH₃OH, (CH₃NH₃)₂SO₄, (CH₃NH₃)₃PO₄, (CH₃NH₃)₂CO₃, CH₃NH₃OH), and any combination of these. In some embodiments of the invention, the chemical formula of at least one cation of a coating oxysalt comprises a metal and/or a metalloid element. In some embodiments of the invention, the chemical formula of at least one cation of a coating oxysalt comprises a metal element. In some embodiments of the invention, the cation of a coating oxysalt is a metal ion. Exemplary cations of a coating oxysalt include, but are not limited to, Pb²⁺, Sn²⁺, Cs⁺, and any combination of these.

The term “photoactive device” refers to (i) a device capable of and configured to convert electromagnetic radiation (e.g., X-ray, infrared, ultraviolet, and/or visible light) to electrical energy and/or converting electrical energy to electromagnetic radiation. A photoactive device may be configured to both convert light to electrical energy (e.g., as a solar cell) and convert electrical energy to light (e.g., via electroluminescence), for example depending on the direction of electrical current in the device (e.g., depending on whether electrical power is withdrawn from or supplied to the device). Exemplary photoactive devices include, but are not limited to, a photovoltaic cell (also referred to as a solar cell), a photodiode, and a light emitting diode (LED). In some embodiments, a photoactive device may also refer to a device configured to change its optical, physical, and/or electrical properties with change in its exposure to electromagnetic radiation and/or a device configured to change its optical properties in response to a change in input of electrical energy. Exemplary photoactive devices may also include, but are not limited to, a photoresistor, phototransistor, photomultiplier, photoelectric cell, an electrochromic cell, a radiation detector, an X-ray detector, and a gamma-ray detector.

In some embodiments, the term “active layer” refers to a layer, of a photoactive device, which absorbs the photons that are converted to electrical energy or which emit the photons which are formed in response to input electrical energy. In some embodiments, an active layer is the layer of a photoactive device which absorbs photons and exhibits a change in at least property, such as resistance of the active layer. In a photovoltaic cell, an active layer may also be referred to as an absorber layer. A photoactive device may have more than one active layer. In some embodiments, an active layer of a photoactive device is a perovskite layer, or layer comprising a perovskite material.

The terms “power conversion efficiency,” “PCE,” “photovoltaic efficiency”, and “solar cell efficiency,” may be used interchangeably and refer to the ratio of energy output from the photovoltaic device to the energy input to the photovoltaic device. The energy output is in the form of electrical energy and energy input is in the form of electromagnetic radiation (e.g., sunlight). Unless otherwise indicated, the photovoltaic efficiency refers to terrestrial photovoltaic efficiency, corresponding to AM1.5 conditions, where AM is Air Mass. PCE may be measured by one or more techniques conventionally known to one of ordinary skill in the art.

The term “ambient air” refers to a gaseous atmosphere that is substantially air having a composition comprising substantially 78% nitrogen and substantially 21% oxygen. In some embodiments, the nitrogen and oxygen concentrations of ambient air is not substantially manipulated artificially or otherwise by human interaction. In some embodiments, ambient air has a temperature that is room temperature. Unless otherwise noted, room temperature refers to a temperature selected from the range of 15° C. to 25° C., or 59° F. to 77° F. Preferably for some embodiments, ambient air has a relative humidity selected from the range of 0% to 80%, preferably for some applications 10% to 80%, preferably for some applications less than 30%, and preferably for some applications 60±10%.

The term “illumination equivalent to 1 sun” refers to an illumination (radiation) intensity and/or electromagnetic spectrum of illumination that substantially approximates or is substantially equivalent to terrestrial solar intensity and/or electromagnetic spectrum. Preferably for some applications illumination equivalent to 1 sun refers to a light intensity, or power density, of at least 70±10 mW/cm², preferably for some applications at least 70 mW/cm², preferably for some applications 100±20 mW/cm², and more preferably for some applications 100±10 mW/cm². Preferably for some applications illumination equivalent to 1 sun refers to (i) illumination characterized by an electromagnetic spectrum corresponding substantially to the global standard spectrum AM1.5G, where AM refers to air mass. Preferably for some applications illumination equivalent to 1 sun refers to a light intensity, or power density, of at least 70±10 mW/cm², preferably for some applications at least 70 mW/cm², preferably for some applications 100±20 mW/cm², and more preferably for some applications 100±10 mW/cm² and (ii) the illumination being characterized by an electromagnetic spectrum corresponding substantially to the global standard spectrum AM1.5G, where AM refers to air mass. Illumination equivalent to 1 sun may be obtained via a simulated solar spectrum using equipment and techniques known in the art and available to one of skill in the art.

The term “orthogonal solvent” refers to a solvent, or mixture of solvents, that substantially does not dissolve the perovskite material being exposed to the orthogonal solvent but substantially does dissolve one or more precursor oxysalts to which the perovskite material is exposed. In some embodiments, an orthogonal solvent substantially dissolves a precursor oxysalt but does not substantially dissolve a coating oxysalt formed via a reaction involving the precursor oxysalt and a perovskite material.

The term “photocurrent hysteresis” refers to a difference between photocurrent of a photoactive device, such as a solar cell, when scanned in a forward direction (e.g., negative voltage bias toward positive voltage bias) versus when scanned in a backward direction (e.g., positive voltage bias toward negative voltage bias).

The term “perovskite material” refers to a material or compound that is characterized by a perovskite crystal structure. A perovskite material may be inorganic, such as, but not limited to, CsPbI₃, wherein the chemical formula of the perovskite material does not comprise carbon (C). A perovskite material may be organic-inorganic, such as, but not limited to, MAPbI₃ and Cs_{0.05}FA_{0.81}MA_{0.14}PbI_{2.55}Br_{0.45}, wherein the chemical formula of the perovskite material comprises organic and inorganic compounds.

The term “substantially” X, “substantially equal to” X, or “substantially equivalent to” X, when used in conjunction with a reference value X describing a property or condition, refers to a value that is within 20%, preferably for some applications within 10%, preferably for some applications within 5%, still more preferably for some applications within 1%, and in some embodiments equivalent to the provided reference value X.

The term “solubility”, as used herein, refers to the ability of a chemical species, such as an oxysalt, to dissolve in a liquid solvent(s), such as water. The term “solubility limit”, when referring to a chemical species, is the maximum concentration at which the chemical species may be dissolved in a solvent, for a given temperature and pressure, before the chemical species precipitates out of solution or beyond which no further amount of the chemical species will dissolve in the solvent.

“Electronic communication” also refers to the ability of two or more materials and/or structures that are capable of transferring charge between them, such as in the form of the transfer of electrons. In some embodiments, components in electronic communication are in direct electronic communication wherein an electronic signal or charge carrier is directly transferred from one component to another. In some embodiments, components in electronic communication are in indirect electronic communication wherein an electronic signal or charge carrier is indirectly transferred from one component to another via one or more intermediate structures, such as circuit elements, separating the components.

In an embodiment, a composition or compound of the invention, such as an alloy or precursor to an alloy, is isolated or substantially purified. In an embodiment, an isolated or purified compound is at least partially isolated or substantially purified as would be understood in the art. In an embodiment, a substantially purified composition, compound or formulation of the invention has a chemical purity of 95%, optionally for some applications 99%, optionally for some applications 99.9%, optionally for some applications 99.99%, and optionally for some applications 99.999% pure.

### DETAILED DESCRIPTION

In the following description, numerous specific details of the devices, device components and methods of the present invention are set forth in order to provide a thorough explanation of the precise nature of the invention. It will be apparent, however, to those of skill in the art that the invention can be practiced without these specific details.

The passivation method reported so far for halide perovskites is still fundamentally different from that in silicon solar cells where involves primary chemical bonding. For the silicon technology, the surface structural defects are generally passivated by silicon oxide, silicon nitride, or aluminum oxide which strongly bond to silicon by covalent bonding. The oxides or nitrides are mechanically strong, compact, and chemically stable which protect silicon from degradation. In addition, the wide bandgap oxides and nitrides passivate the surface defects by eliminating Si dangling bonds and thus enhance device efficiency. However, there is still no such a passivation layer reported so far to form primary chemical bonding with perovskites. Embodiments disclosed herein include a generic strategy to form a thin, compact coating oxysalt layer (e.g., inorganic oxysalt layer) on the surface of perovskite material by in-situ reaction of perovskite with certain inorganic anions. The formed surface coating oxysalt layer features with much better resistance to many hazardous stimuli under ambient atmosphere and light irradiation, and its passivation effect enhances the efficiency of the perovskite solar cells. The perovskite materials, electronic devices, and methods disclosed herein address these and other challenges, including those described above.

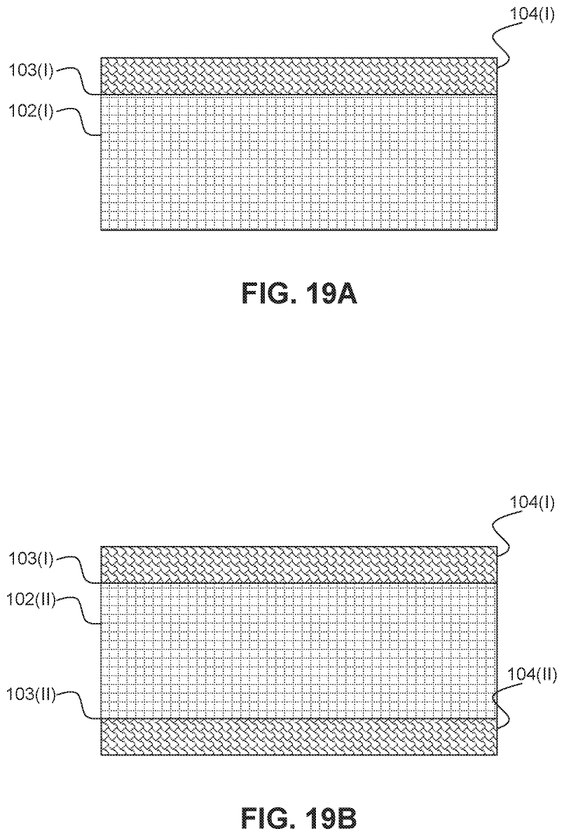

FIG. 19A is a schematic of a perovskite material 102(I), according to certain embodiments disclosed herein. Perovskite material 102(I) comprises a coating layer 104(I) on at least a portion of a surface 103(I) of perovskite material 102(I). Coating layer 104(I) comprises a coating oxysalt. Perovskite material 102(I) may have a plurality of surfaces, each of which optionally comprises a coating layer such as coating layer 104(I), according to certain embodiments. For example, FIG. 19B is a schematic of perovskite material 102(II), according to some embodiments disclosed herein, have surface 103(I) and a surface 103(II). Perovskite material 102(II) comprises a coating layer 104(I) on at least a portion of a surface 103(I) and a coating layer 104(II) on at least a portion of surface 103(II) of perovskite material 102(II). Coating layers 104(I) and 104(II) each independently comprises a coating oxysalt.

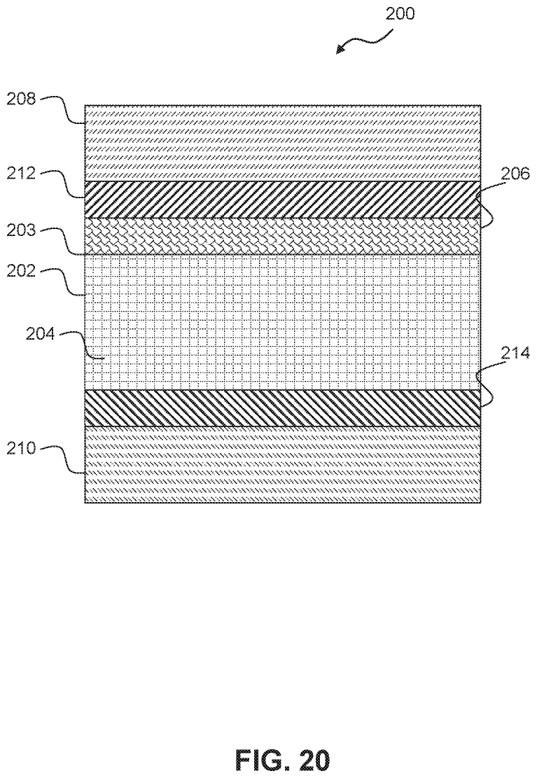

FIG. 20 is a schematic of an electronic device 200. Electronic device 200 comprises a first layer 202. First layer 202 comprises a perovskite material 204 and first layer 202 comprises a surface 203. Electronic device 200 further comprises a coating layer 206 disposed on at least a portion of surface 203 of layer 202. In some embodiments, electronic device 200 further comprises a positive electrode 208 and a negative electrode 210. Each of positive electrode 208 and negative electrode 210 is independently in electronic communication with perovskite material 204 of first layer 202. Optionally, at least one of positive electrode 208 and negative electrode 210 is characterized as a substantially transparent material, such as a transparent conducting oxide (“TCO”) or other electrically conducting material that exhibits transparency with respect to wavelengths of the electromagnetic spectrum of relevance for a particular application (e.g., visible light wavelengths are relevant to traditional solar cells). In some embodiments, electronic device 200 further comprises an electron transport layer 214. Electron transport layer 214 is in electronic communication with perovskite material 204, of first layer 202. Electron transport layer 214 may be positioned between first layer 202 and negative electrode 210. In some embodiments, electronic device 200 further comprises a hole transport layer 212. Hole transport layer 212 is in electronic communication with perovskite material 204, of first layer 202. Hole transport layer 212 may be positioned between first layer 202 and positive electrode 208. In some embodiments, a plurality of surfaces of first layer 202 has a coating layer, such as coating layer 206, disposed thereon. U.S. patent application Ser. No. 16/130,797, titled “Insulating Tunneling Contact for Efficient and Stable Perovskite Solar Cells” and U.S. patent application Ser. No. 15/691,479, titled “Self-Powered GHz Solution-Processed Hybrid Perovskite Photodetectors”, which are each incorporated by reference herein, disclose various useful materials and methods for various electronic device layers, including, for example materials and methods useful for positive electrode layer(s), negative electrode layer(s), active layer(s), hole transport layer(s), electron transport layer(s), and other device layers.

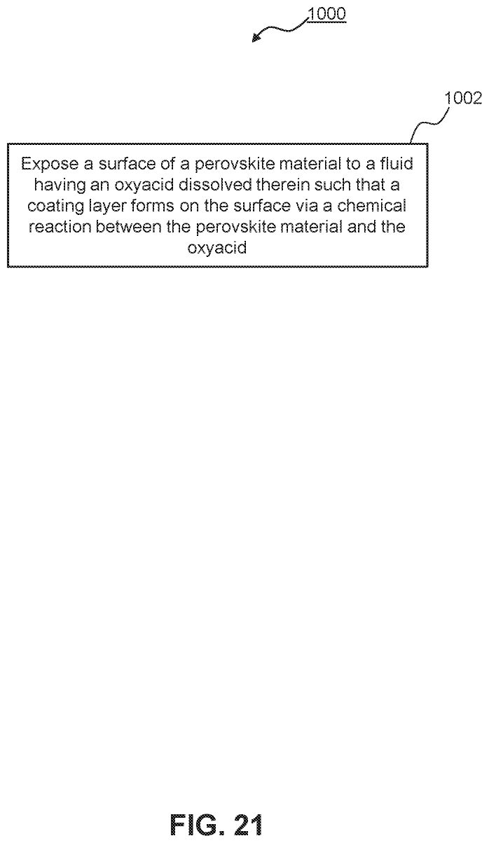

FIG. 21 is a flowchart depicting a method 1000, according to certain embodiments, for forming a coating layer on a surface of a perovskite material. Method 100 comprises step 1002. Step 1002 comprises exposing a surface of a perovskite material to a fluid having a precursor oxysalt dissolved therein such that a coating layer forms on the surface via a chemical reaction between the perovskite material and the precursor oxysalt.

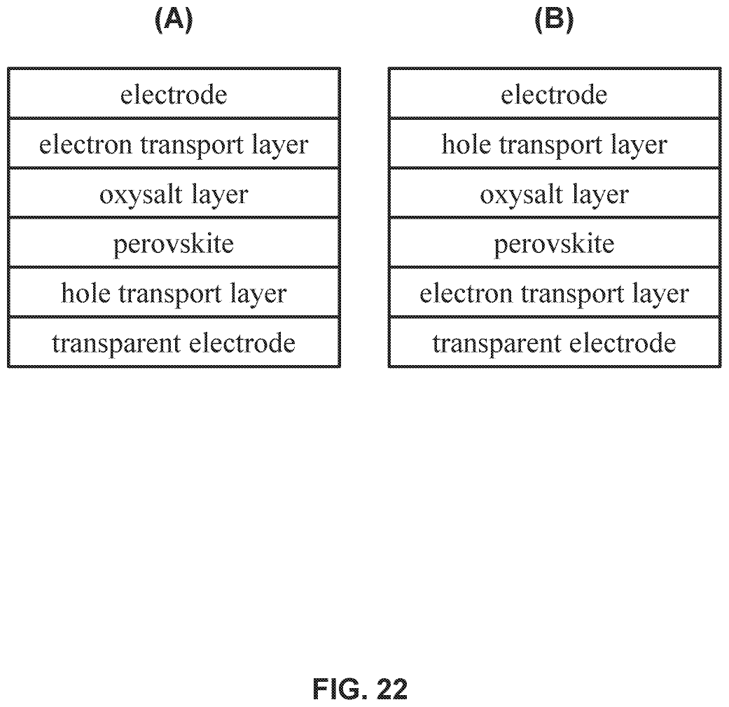

Each of panels A and B of FIG. 22 shows an embodiment of an electronic device. The electronic devices of panels A and B differ in the configuration of the device layers. For example, the device of panel A has a hole transport layer positioned between a perovskite layer and a transparent electrode (e.g., a positive electrode) and the device of panel B has an electron transport layer positioned between a perovskite layer and a transparent electrode (e.g., a negative electrode). The negative electrode, the positive electrode, or each of both electrodes independently may be a transparent electrode, such as a TCO or other acceptable transparent conducting electrode material. Optionally, the electronic devices of FIGS. 20 and 22 include other layers not shown.

The invention can be further understood by the following non-limiting description and examples.

Oxides have been shown importance for the success of many semiconductor technologies such as silicon for their multiple functions including protecting and passivating the semiconductor surfaces. Here, we show that converting the surfaces of organic-inorganic halide perovskite to water-insoluble lead (II) coating oxysalt(s) by its reaction with sulfate or phosphate ions can effectively stabilize the surfaces of perovskite materials by forming coating layer(s) comprising coating oxysalt(s). These coating oxysalt thin layers enhance the resistance of the perovskite films to the attacking of environmental hazards due to the formation of primary chemical bonding. Wide-bandgap Pb-oxysalt coating layers also reduce the defect density on the perovskite surfaces by reaction with defective sites, in addition to the passivation effect due to the wide bandgap. The Pb-oxysalt coating layer(s) elongates the carrier recombination lifetime, and boosts the efficiency of the solar cells to 21.1%. Coated solar cell devices maintain 96% of the initial efficiency after operation at maximum power point under simulated AM 1.5G irradiation for 1200 hours at 65° C.

Formation of surface coating oxysalt layer:

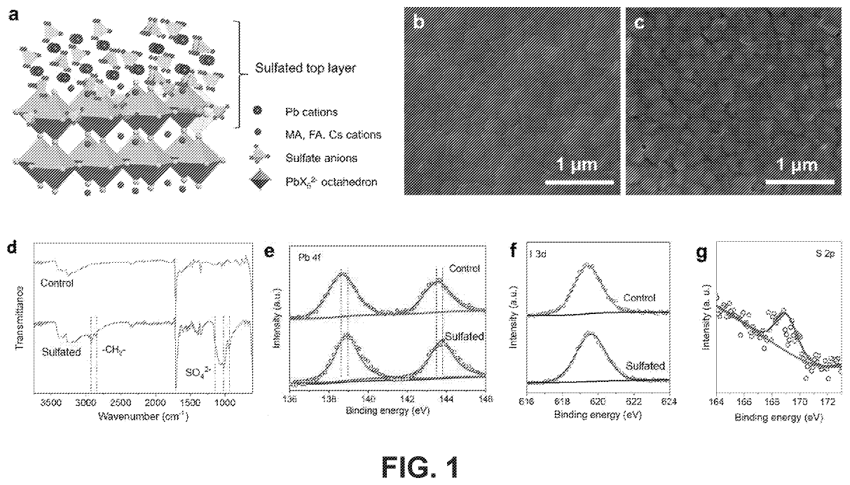

FIG. 1, panel a, illustrates the concept of passivating the organic-inorganic halide perovskite surface using compact coating oxysalt layers. For some applications, coating layers may have large bandgap to reduce surface recombination velocity, and be chemically stable in ambient air, especially under humid condition. We find that some lead salts are insoluble in water which can be employed for the perovskite surface stabilization. For example, the solubility of PbSO₄, Pb₃(PO₄)₂, PbCO₃ and Pb(OH)₂ in water is merely 0.00443, 0.000014, 0.00011, 0.0155 g/100 mL at 20° C., respectively. In contrast, PbI₂ has a much higher solubility of 0.0756 g/100 mL in water. For some applications, it is preferred that the coating layer(s) bond strongly to the perovskite surface so that the coating is mechanically strong to resist the attack of hazards. Here we first demonstrate an approach to perovskite materials with coating layer(s) that may address these desirable features by using PbSO₄ and Pb₃(PO₄)₂ as the surface coating oxysalt layers by using a chemical reaction of perovskite with SO₄²⁻ and PO₄³⁻ containing salts. The SO₄²⁻ and PO₄³⁻ contacting salts need to dissolve in orthogonal solvents that do not dissolve halide perovskites, such as isopropanol or toluene. We thus chose (C₈H16NH₃)₂SO₄ and (C₈H₁₆NH₃)₃PO₄ as precursor oxysalts due to their good solubility in these orthogonal solvents. We show the ions can react with halide perovskite by dipping perovskite films into (C₈H₁₆NH₃)₂SO₄ and (C₈H₁₆NH₃)₃PO₄ solutions for a long time, according to the following chemical equations,

$$\begin{matrix}{MA PbI}_{3} + {SO}_{4}^{2 -} \to M {A}^{+} + 3 {I}^{-} + {PbSO}_{4} & ( 1 ) \\ 3 {MA PbI}_{3} + 2 {PO}_{4}^{3 -} \to 3 M {A}^{+} + 9 {I}^{-} + {{Pb}_{3} ( {PO}_{4} )}_{2} & ( 2 )\end{matrix}$$

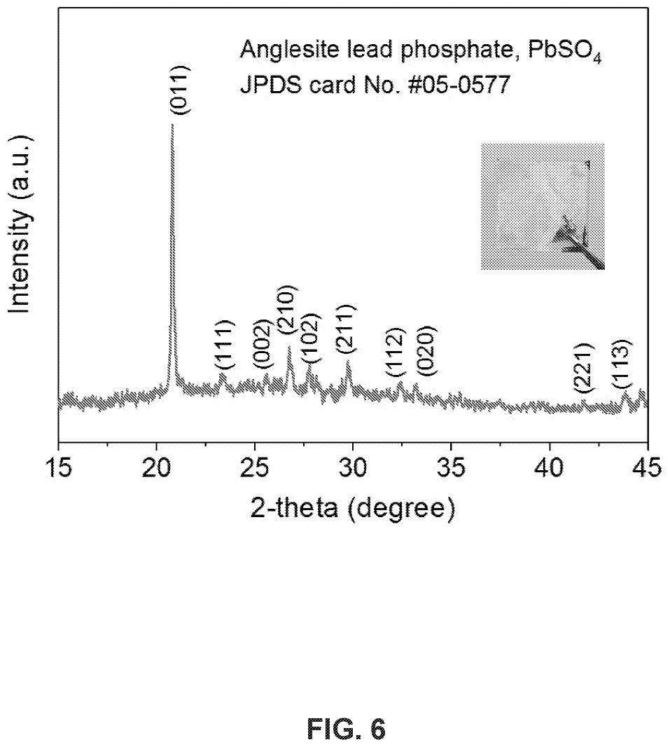

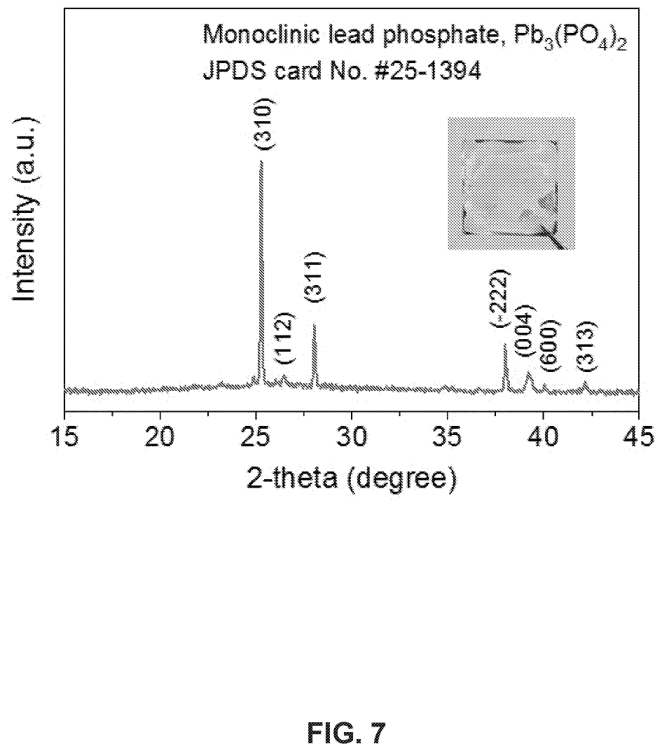

Such reaction yields stable white-colored anglesite Pb SO₄ and Pb₃(PO₄)₂ films, as shown by the photo and verified by X-ray diffraction pattern in FIGS. 6 and 7. Triple cation perovskite was used in some embodiments with the chemical formula of Cs_{0.05}FA_{0.81}MA_{0.14}Pb_{12.55}Br_{0.45}, and hereafter referred as CsFAMA perovskite.

Using the same method, a thin lead sulfate layer can be generated on the surface of CsFAMA perovskite films by reducing the reaction time to 20 s, for example. The scanning electron microscope (SEM) images in FIG. 1 (panel b, panel c) show that the topography of the perovskite films remains unchanged after the coating oxysalt layer formation, indicating a conformal coating of Pb SO₄ and Pb₃(PO₄)₂ on the perovskites.

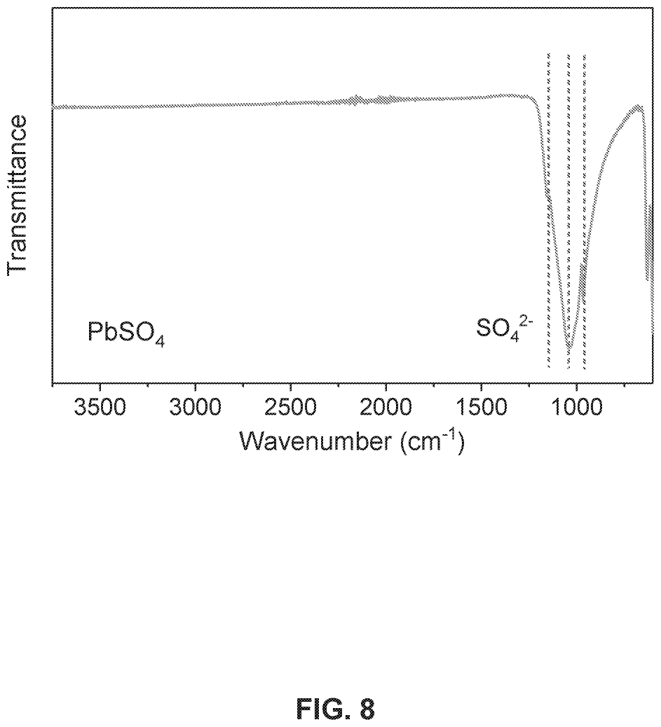

Fourier transform infrared (FT-IR) transmission spectra of CsFAMA perovskite powders before and after surface treatment were collected to probe the interactions of sulfate ions with CsFAMA perovskite. The tetrahedral symmetric sulfate ions typically present one broad peak at approximately 1100 cm⁻¹ of the triply degenerate v3 band.²³ Here several new peaks appeared as shown in FIG. 1, panel d. The occurrence of vl band (945 cm⁻¹) and splited v3 bands (950˜1200 cm⁻¹) suggests a distortion of the tetrahedral structure of sulfate ions, indicating the formation of a strong ionic binding between Pb²⁺ and SO₄²⁻ ions.²⁴ The characteristic vibration peaks of the sample locate at the identical position (950˜1200 cm⁻¹) with that of pure PbSO₄ powder, which implies the formation of a coating oxysalt layer on the perovskite surface (FIG. 8). We performed X-ray photoemission spectroscopy (XPS) measurements to measure the perovskite surface composition after reaction, and the results are shown in FIG. 1, panels e-g. The Pb 4f spectrum exhibits two contributions, 4f_{7/2} and 4f_{5/2}, resulting from the spin-orbit splitting, located at 138.6 and 143.5 eV for the control film, respectively.²⁵ The shift of the Pb peaks toward higher binding energies provides evidence for the formation of stronger ionic bonding between Pb²⁺ and SO₄²⁻ ions.²⁶ The S/Pb atom ratio was estimated to be 1.03 by the integrated area of S 2s and Pb²⁺ peaks (FIG. 1, panel).²⁷

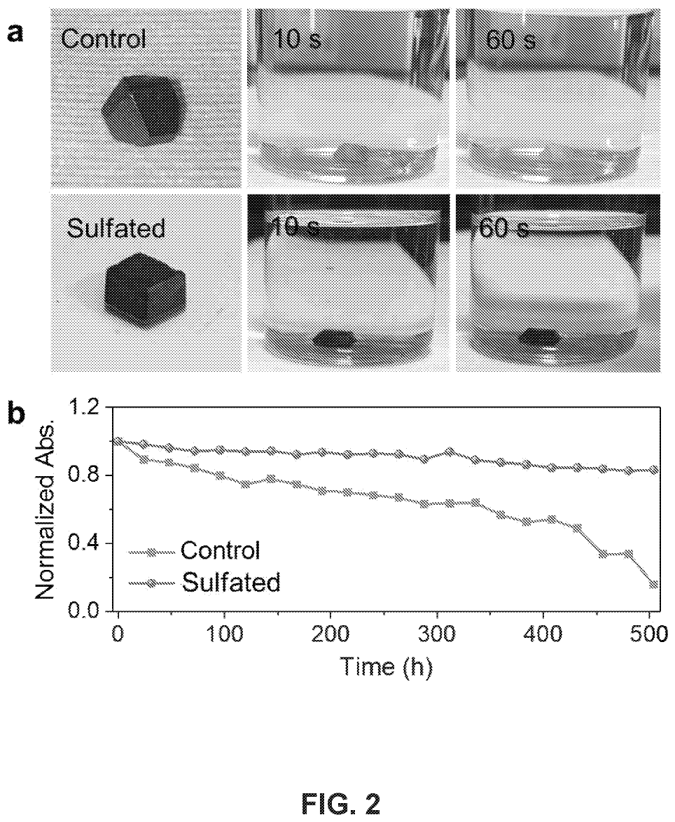

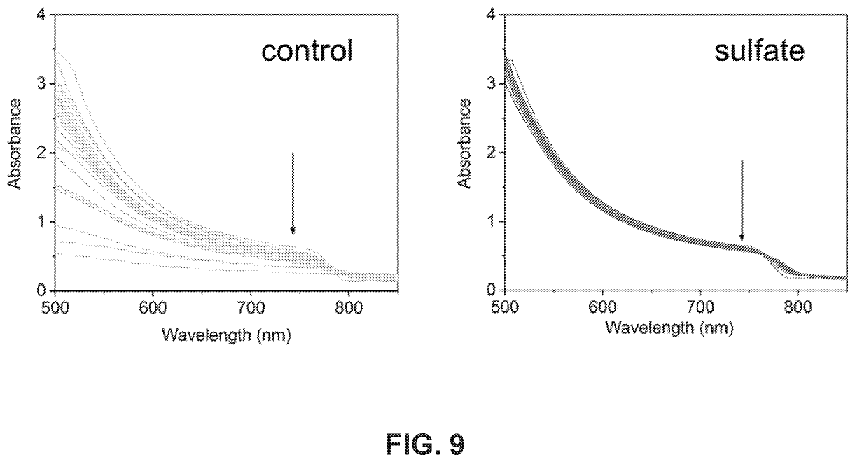

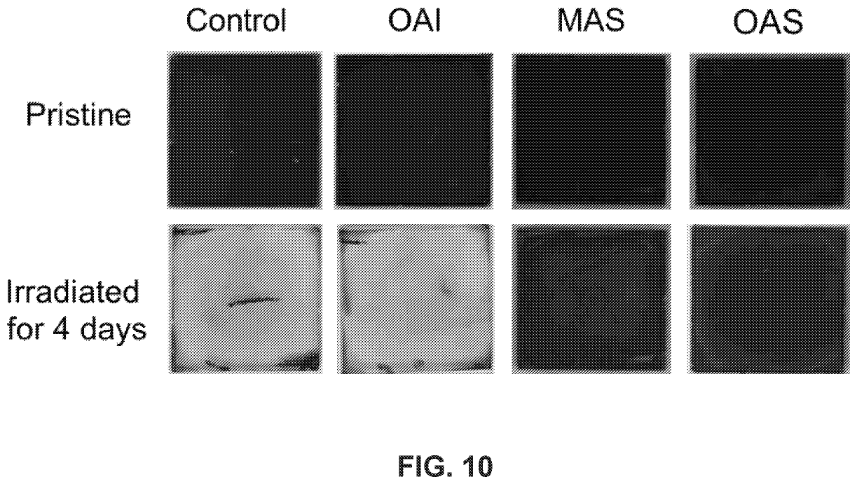

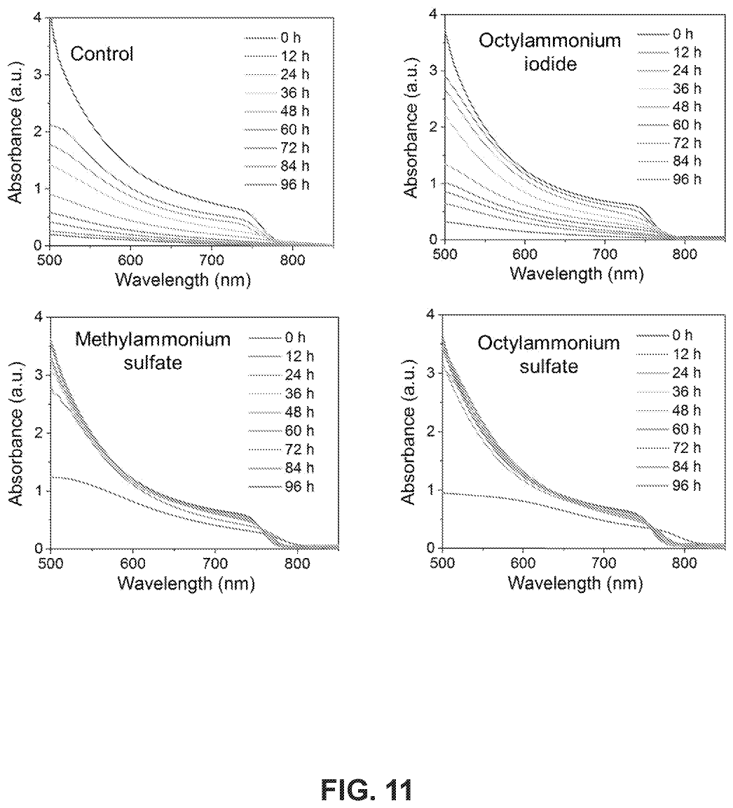

In ambient condition, hydration and oxidization of perovskites are among main paths for the degradation of perovskite films.^{28,29} We investigate the water resistance of perovskites with sulfated top layers on MAPbI₃ single crystals. MAPbI₃ crystals were treated with the sulfate precursor solution followed by thermal annealing for 10 min in an oven at 100° C., and the details can be found in the experimental section. When dipped in water, the control MAPbI₃ crystal without any treatment quickly turned into yellow within 10 s, due to fast reaction of MAPbI₃ with water, forming PbI₂ or other hydrates, whereas the sample with a sulfated layer remained black after dipping in water for >60 s. The much later appearance of yellow PbI₂ from perovskite single crystals proves the sulfated top layer is compact enough to slow down the permeation of water into perovskite. We then tested the protection effect of coating oxysalt layer on polycrystalline films with which has the same stacking structure of the real devices but without metal electrodes. The perovskite films with the coating oxysalt layer was sandwiched between poly(triaryl amine) (PTAA) and phenyl C₆₁ butyric acid methyl ester (PCBM) layers. (A coating layer having a coating oxysalt, such as coating layer 104, may also be referred to, hereinafter, as an “oxide layer”.) The sulfated CsFAMA perovskite films appeared to be black after being illuminated at 1 sun light intensity in air for 500 hours (FIG. 9). The absorbance changes at 740 nm was recorded during the stability test to quantify the material degradation. The control sample lost 84.2% of its absorption after illumination for 504 hours, while the sulfate-treated sample only lose 16.8% (FIG. 2, panel a). Since ammonium cations have also been reported to enhance the stability of perovskites,³⁰ another set of perovskite thin films were tested in air under illumination without any charge transport layers to study which species, specifically ammonium or sulfate ions, play(s) the dominating role of stabilization. The CsFAMA perovskite film treated with octylammonium iodide fully bleached after testing for four days, which is comparable the degradation rate of the control sample without any ion additives (FIGS. 10 and 11). With sulfate ions, perovskite films still remained black after four days. About 56% and 64% of the films' absorbance at 740 nm remained for films treated with methylammonium sulfate and octylammonium sulfate, respectively. The result verified the stabilization should be mainly ascribed to sulfate ions, rather than ammonium ions.

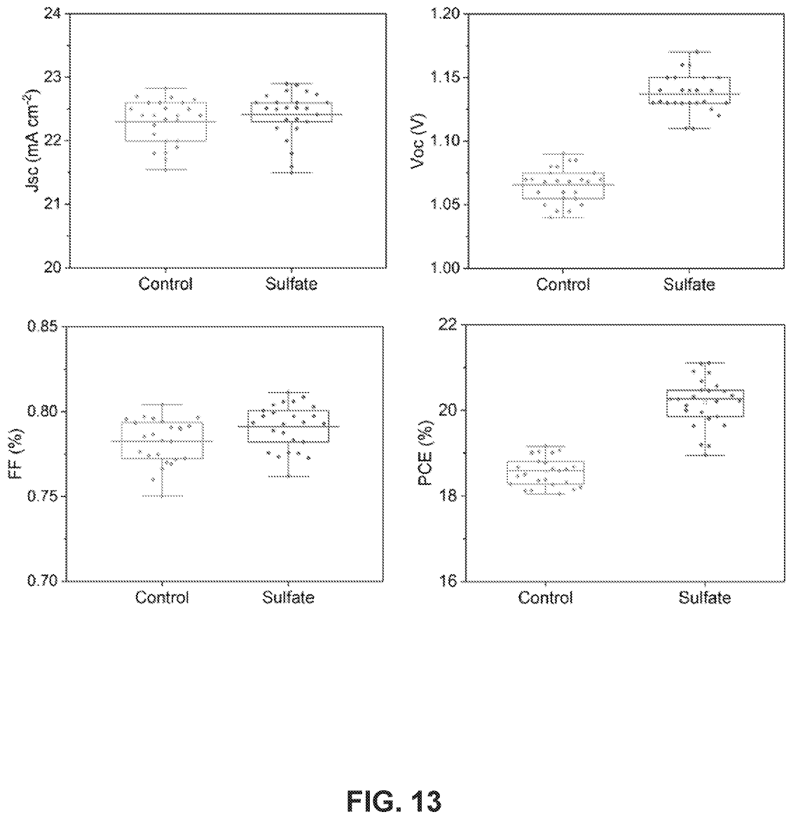

Mass transport of ions is another important issue that limits the stability of the encapsulated halide perovskite devices. Ion migration is significantly enhanced under illumination,⁻which may change the composition and morphology of perovskite films by forming pin-holes, in addition to causing the degradation of charge transport layers and electrodes.^{32,33} We also show that ion migration is easier at extended defects such as film surface and grain boundaries.^{÷}the formation of a layer comprising coating oxysalt(s) with strong ionic chemical bonding may stabilize the perovskite surface and suppress the ion migration through it. We measured the activation energy (Eₐ) for ion migration of perovskite films by temperature-dependent electrical conductivity. Lateral structure devices were fabricated by thermal evaporation of two Au electrodes on PTAA/perovskite/PCBM films. The activation energy can be extracted by Nernst-Einstein relation: σ(T)=(σ₀T)exp(−Eₐ/KT), where k is the Boltzmann constant, σ₀ is a constant, and T is temperature. The applied electric field was fixed to be 0.4 V/μm, which is close to the operation electric field in solar cell devices. For the CsFAMA perovskite films, ionic conductivity begins to dominate the total conductivity with an Ea of 0.288 eV when temperature is increased to 314 K in the dark. When illuminated at 0.1 sun light intensity, the transition temperature is reduced to be 273 K, accompanied with a lower Ea of 0.104 eV. This observation agrees well with other results that light would facilitate the ion migration.³¹ For the sulfate-treated perovskite film, we did not observe such a transition from electronic to ionic conductivity when the temperature was increased up to 330 K both in the dark and under illumination. A constant slope was obtained with an Ea of 0.036 eV, which should be ascribed to electronic conduction. We thus conclude that ion migration is efficiently suppressed by the sulfated top layer on the surface of perovskite polycrystalline films. The reason may be that the surface defects, such as vacancies, are immobilized by the strongly bonded sulfated layer. This also may explain the restrained morphological variation of perovskite films with the presence of a sulfated layer (FIG. 13).

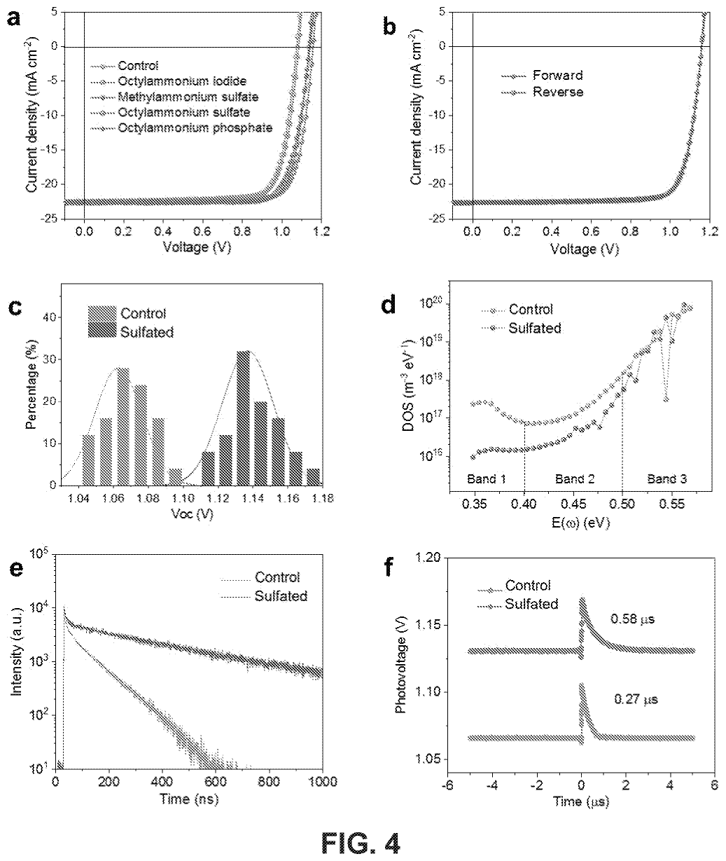

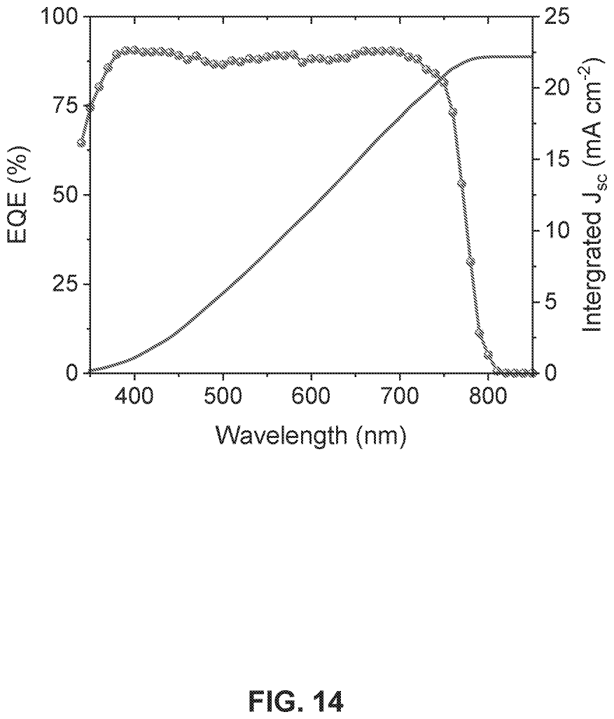

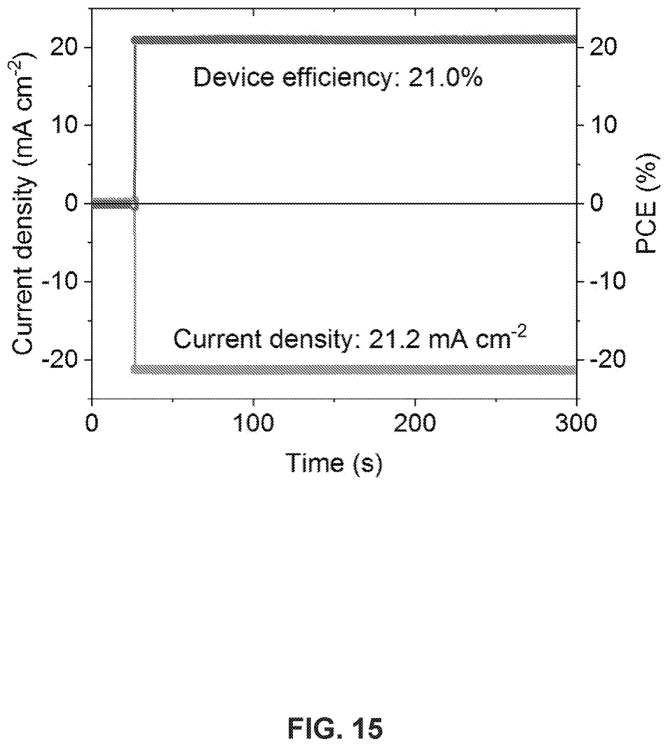

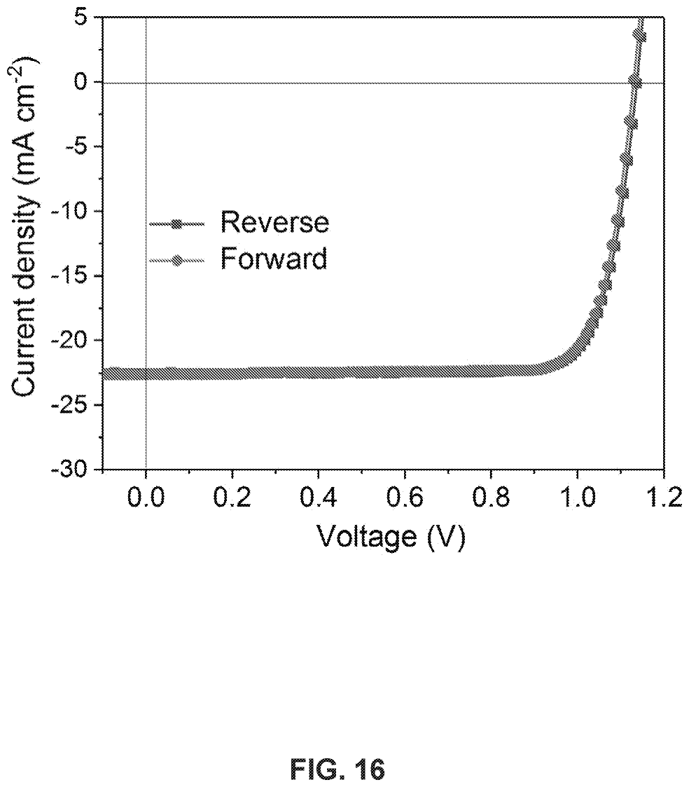

Solar cells were fabricated with a p-i-n planar heterojunction configuration structured as indium tin oxide (ITO) glass substrate/PTAA/CsFAMA perovskite /fullerene (C₆₀)/2,9-dimethyl-4,7-diphenyl-1,10-phenanthroline (BCP)/copper (Cu). FIG. 4, panel a, shows current density-voltage (J-V) characteristics of champion devices, measured under simulated sunlight AM1.5G, and the device performance parameters are summarized in Table 1. The control device has a short-circuit current density (Jsc) of 22.51 mA cm⁻², an open-circuit voltage (Voc) of 1.07 V and a fill factor (FF) of 0.796, yielding a power conversion efficiency (PCE) of 19.16%. The octylammonium iodide treated perovskite device exhibits a comparable PCE of 19.28% with a Jsc of 22.49 mA cm⁻², a Voc of 1.08 V and a FF of 0.794. In contrast, the devices with the methylammonium sulfate treatment shows a significantly improved performance with a Jsc of 22.62 mA cm⁻², a Voc of 1.14 V, a FF of 0.794 and a PCE of 20.60%. After substituting methylammonium with octylammonium, the device delivers a Jsc of 22.63 mA cm⁻², a Voc of 1.16 V, a FF of 0.804 and a PCE of 21.11%, without notable hysteresis in photocurrent (FIG. 2, panel b, and Table 2). The average PCE of the sulfate-treated devices reaches 20.18±0.56% (FIG. 13). The enhanced. Voc and PCE as well as hysteresis-free behavior of the sulfate-treated devices together indicate the surface charge traps are passivated by the sulfated top layer. The Jsc value obtained from the J-V characteristics was also verified by external quantum efficiency (EQE) obtained by the integration of the spectral response as shown in FIG. 14. This device was further held at maximum power point (MPP) with voltage of 0.99 V to track the stabilized power output. As shown in FIG. 15, the photocurrent stabilized at approximately 21.2 mA cm⁻², giving a stabilized PCE of 21.0%. We further demonstrated the universality of this synthetic strategy of using phosphate ions to form a Pb₃(PO₄)₂ surface layer and examined the device performance. Solar cell device based on phosphated CsFAMA perovskite exhibits a Jsc of 22.54 mA cm⁻², Voc of 1.14 V and a FF of 0.813, yielding a PCE of 20.87% without hysteresis (FIG. 16 and Table 3).

The Voc of the devices with and without sulfate treatment was analyzed and the statistical distribution is shown in FIG. 4, panel e. The average Voc are 1.07 and 1.14 V for the control and sulfate-treated devices, respectively. Trap density of states (tDOS) of the control and sulfate-treated devices were measured by thermal admittance spectroscopy. FIG. 4, panel d, describes that the device with sulfated top layers has the lower tDOS almost over the whole trap depth region. The density of shallower trap states (0.35-0.42 eV) of sulfate-treated device is at least 10 folds lower than that of the control device. Other characterizations have revealed that the shallow traps mainly locate at the grain boundaries.³⁴ Therefore, this result indicates that the sulfate ions can effectively reach the grain boundaries during the treatment and passivate them, subsequently increasing the device Voc.

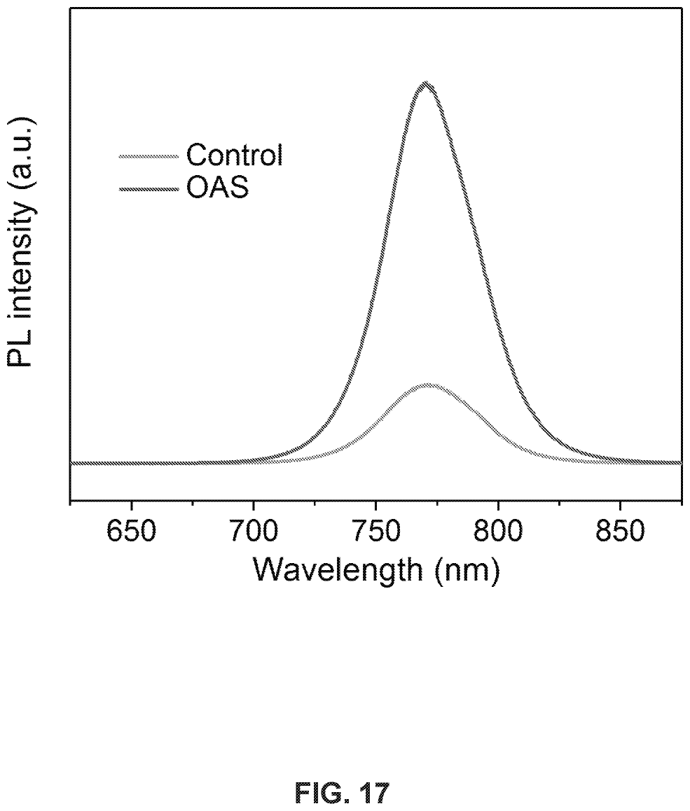

The time-resolved photoluminescence (TRPL) spectra of the control CsFAMA perovskite film show a bi-exponential decay with a fast and a slow component (FIG. 4, panel e). We noticed that the existence of surface layer mainly impacted the fast PL decay process. The fast-component of the recombination process from the control and sulfate-treated films were fitted to be 3.2 and 24.7 ns, respectively, which is consistent with the enhanced steady-state PL results (FIG. 17). The enhanced PL intensity and PL decay lifetime illustrate that the non-radiative recombination of photo-generated carriers in perovskite films is reduced by the formation of sulfated surface layers.^{36,37} Devices were then irradiated under AM 1.5G simulated illumination, and weak laser pulses (337 nm, 4 ns) were used to modulate the Voc to measure the decay of transient photovoltage signals. As seen in FIGS. 4, panel f, and 18, the charge-recombination lifetime under 1 sun illumination was increased from 0.27 μs for the control device to 0.58 μs and 0.47 μs for sulfate and phosphate treated devices. The lower charge trap density and longer carrier recombination lifetime of samples with sulfated top layers indicates the reaction of sulfate and phosphate ions with defective perovskite surface reduce the surface defect density, in addition to the charge compensation effect of these ions. The large bandgap coating layer should also contribute to the reduced the surface charge recombination rate, similar to the passivation of silicon by oxides.³⁸

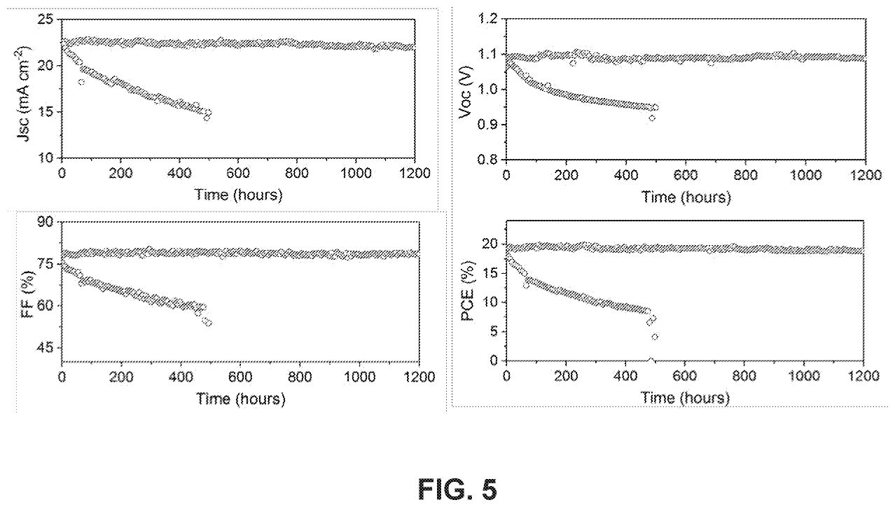

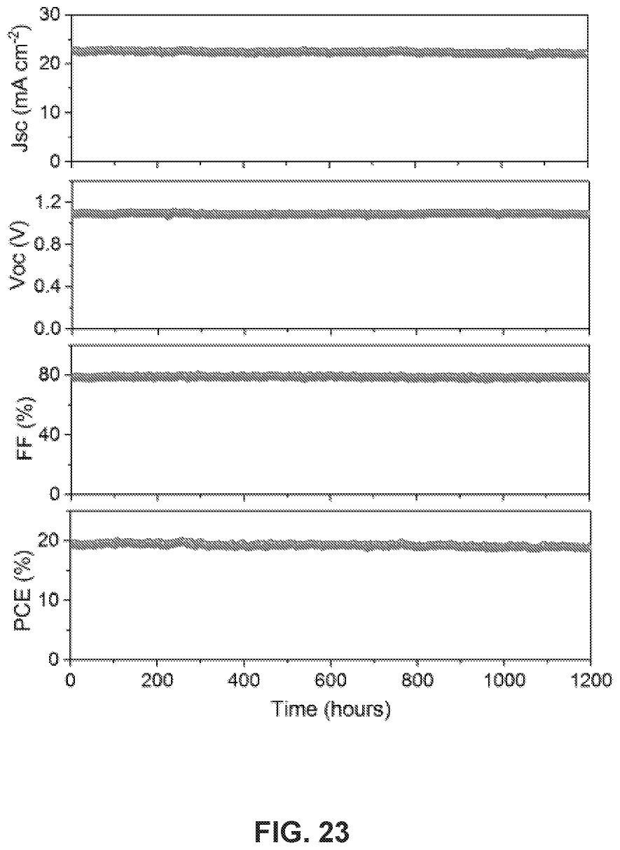

Device stability: We performed long-term stability tests of encapsulated CsFAMA perovskite devices under a plasma lamp with light intensity equivalent to AM1.5G, without an ultraviolet filter, in air (relative humidity ˜60±10%). All devices were loaded with a resistance so that they worked at maximum power point (MPP) at the beginning of the tests. The J-V curves were automatically recorded with reverse scan rate of 0.1 V s⁻¹ every six hours. We frequently checked the stabilized efficiency during degradation and did not find obvious difference between the stabilized efficiency and that from J-V scanning. The temperature of the devices under illumination was measured to be ˜65° C. due to the heating effect of light. As shown in FIG. 5, the PCE of the encapsulated control device degraded rapidly from 18.23% to 8.54% after testing for 474 h. For the sulfate-treated devices, the PCE slightly improved during the first 120 h of testing, and then followed by degradation with linearly reduced Jsc and FF over time. After 1200 h testing, the efficiency slightly dropped to 96.8% of the initial value (see also FIG. 23 for stability data corresponding to sulfate-treated devices). This makes it among the most stable CsFAMA perovskite devices reported so far tested at MPP.

Summary: We disclosed a strategy to convert the perovskite surface to compact oxide layers (coating layers comprising coating oxysalt(s)) for simultaneous stabilization and passivation of perovskite surfaces, which increased the PCE of the CsFAMA perovskite devices to 21.1%. The devices show long operational time of 1200 h with minimal efficiency loss. A difference of this methodology compared with the conventional electronic trap state passivation is that the passivation layer actually forms a strong ionic bonding with perovskites, in contrast to the weak secondary bonding in other organic passivation molecules, and the formation of this passivation layer is actually the process the surface defects are eliminated. Our current studies have illustrated the universality of the method by using Pb SO₄ and Pb₃(PO₄)₂ layers. More inorganic materials are also promising and accessible, such as PbCO₃, Pb(OH)_{2.} This study offers a new pathway for passivation of perovskite-based devices that is comparable to the well-developed silicon photovoltaics and enable the production of stable and highly efficient solar cells that can survive under environmental stressors. Finally, this method can be broadly used in perovskite electronic devices in eventually all perovskite compositions and material forms. We tested its capability of protect perovskite single crystal radiation detectors which yield positive results.

Exemplary experimental details according to certain embodiments:

Device fabrication: Patterned ITO glass substrates were first cleaned by ultrasonication with soap, acetone and isopropanol. The hole transport layer poly(bis(4-phenyl)(2,4,6-trimethylphenyl)amine) (PTAA) with a concentration of 2 mg ml⁻¹ dissolved in toluene was spin-coated at the speed of 4,000 rpm for 35 s and then annealed at 100° C. for 10 min. Before depositing perovskite films, the PTAA film was pre-wetted by spinning 80 μl DMF at 4,000 rpm for 15 s to improve the wetting property of the perovskite precursor solution. The perovskite precursor solution composed of mixed cations (lead (Pb), cesium (Cs), formamidinium (FA) and methylammonium (MA)) and halides (I, Br) was dissolved in mixed solvent (DMF/DMSO=4:1) with a chemical formula of Cs_{0.5}FA_{0.81}MA_{0.14}PbI_{2.55}Br_{0.45.} Then 80 μl precursor solution was spun onto PTAA at 2,000 rpm for 2 s and 4,000 rpm for 20 s, and the film was quickly washed with 130 μl toluene at 18 s during spin-coating. Subsequently, the sample was annealed at 65° C. for 10 min and 100° C. for 10 min. The ammonium sulfate solution was prepared by dissolving corresponding ammonia and sulfuric solution in mixed solvents (toluene/isopropanol =5:1) with the concentration of 0.04 mM. To treat the surface of perovskite films, 100 μl of precursor solution was loaded on the film for 20 s and was then spun at 6,000 rpm for 30 s. During spin-coating process, extra 130 μl of toluene was dropped to wash the unreacted precursors. The devices were finished by thermally evaporating C₆₀ (30 nm), BCP (8 nm) and copper (140 nm) in sequential order.

Characterization

Crystallographic information for the as-synthesized crystals was obtained by a Rigaku D/Max-B X-ray diffractometer with Bragg-Brentano parafocusing geometry, a diffracted beam monochromator, and a conventional cobalt target X-ray tube set to 40 kV and 30 mA. The X-ray photoelectron spectroscopy (XPS) was measured (SPECS XR-MF) by using a monochromatized Al source (hv=1486.6eV). The Fourier transform infrared (FT-IR) spectra of perovskite powder were collected in the transmittance mode on the PerkinElmer IR spectrometer instrument in the 400˜4,000 cm⁻¹ region. The morphology and structure of the samples were characterized by Quanta 200 FEG environmental scanning electron microscope. Optical absorption spectra were measured by means of an Evolution 201/220 UV/visible Spectrophotometer. Activation energy for ion migration was tested using lateral devices by a Keithley 2400 source meter at different temperatures. The electric field of the lateral device was 0.4 V/μm. The device was set in a Lakeshore Probe Station to obtain desired temperature. Time-resolved photoluminescence (TRPL) was performed on the perovskite films grown on varied substrates by a Horiba DeltaPro fluorescence lifetime system, which equipped with a DeltaDiode (DD-405) pulse laser diode with wavelength of 404 nm. The laser excitation energy in the measurement was 20 pJ pulse⁻¹. The J-V analysis of solar cells was performed using a solar light simulator (Oriel 67005, 150 W Solar Simulator) and the power of the simulated light was calibrated to 100 mW cm⁻² y a silicon (Si) diode (Hamamatsu S1133) equipped with a Schott visible-colour glass filter (KG5 colour-filter). All cells were measured using a Keithley 2400 source meter with scan rate of 0.1 V s⁻¹. The steady-state PCE was measured by monitoring current with the largest power output bias voltage and recording the value of the photocurrent. External quantum efficiency curves were characterized with a Newport QE measurement kit by focusing a monochromatic beam of light onto the devices. The tDOS of solar cells were derived from the frequency-dependent capacitance (C-f) and voltage dependent capacitance (C-V), which were obtained from the thermal admittance spectroscopy (TAS) measurement performed by an LCR meter (Agilent E4980A). The transient photovoltage was measured under 1 sun illumination. An attenuated UV laser pulse (SRS NL 100 Nitrogen Laser) was used as a small perturbation to the background illumination on the device. The laser-pulse-induced photovoltage variation and the Voc is produced by the background illumination. The wavelength of the N2 laser was 337 nm, the repeating frequency was about 10 Hz, and the pulse width was less than 3.5 ns.

TABLE 1
Summary of the best device performance of solar cells treated
with different precursor solutions. All the J-V curves were measured
under 100 mW cm⁻² simulated AM 1.5G sunlight by reverse voltage
scan (scan rate: 0.1 V s⁻¹).

| | J_{sc}/mA cm⁻² | Voc/V | FF | PCE/% |
|---|---|---|---|---|
| Control | 22.51 | 1.07 | 0.796 | 19.16 |
| Octylammonium | 22.49 | 1.08 | 0.794 | 19.28 |
| iodide | | | | |
| Methylammonium | 22.62 | 1.14 | 0.799 | 20.60 |
| sulfate | | | | |
| Octylammonium | 22.63 | 1.16 | 0.804 | 21.11 |
| sulfate | | | | |
| Octylammonium | 22.54 | 1.14 | 0.813 | 20.87 |
| phosphate | | | | |

TABLE 2
Photovoltaic parameters of the best sulfate device with different
sweeping rates and directions. All the J-V curves were at a simulated
AM 1.5 G solar irradiation with a scan rate of 0.1 V s⁻¹.

| | J_{sc}/mA cm⁻² | Voc/V | FF | PCE/% |
|---|---|---|---|---|
| Forward | 22.65 | 1.16 | 0.803 | 21.09 |
| Reverse | 22.63 | 1.16 | 0.804 | 21.11 |

TABLE 3
Photovoltaic parameters of the best phosphate modified
device with different sweeping rates and directions.
All the J-V curves were at a simulated AM 1.5 G solar irradiation
with a scan rate of 0.1 V s⁻¹.

| | J_{sc}/mA cm⁻² | Voc/V | FF | PCE/% |
|---|---|---|---|---|
| Forward | 22.60 | 1.13 | 0.814 | 20.80 |
| Reverse | 22.54 | 1.14 | 0.813 | 20.87 |

### REFERENCES CITED HEREIN

1 Chen, W. et al. Efficient and stable large-area perovskite solar cells with inorganic charge extraction layers. Science 350, 944-948 (2015).
2 Stranks, S. D. et al. Electron-hole diffusion lengths exceeding 1 micrometer in an organometal trihalide perovskite absorber. Science 342, 341-344 (2013).
3 Shi, D. et al. Low trap-state density and long carrier diffusion in organolead trihalide perovskite single crystals. Science 347, 519-522 (2015).
4 Chen, Z. et al. Thin single crystal perovskite solar cells to harvest below-bandgap light absorption. Nat. Commun. 8, 1890 (2017).
5 Zhou, H. et al. Interface engineering of highly efficient perovskite solar cells. Science 345, 542-546 (2014).
6 National Renewable Energy Laboratory, Best research-cell efficiencies chart; www.nrel.gov.ncpv/images/efficiency_chart.jpg.
7 Yang, S. et al. Functionalization of perovskite thin films with moisture-tolerant molecules. Nat. Energy 1, 15016 (2016).
8 Grätzel, M. The light and shade of perovskite solar cells. Nat. Mater. 13, 838 (2014).
9 Leijtens, T. et al. Stability of metal halide perovskite solar cells. Adv. Energy Mater. 5 (2015).
10 Shin, S. S. et al. Colloidally prepared La-doped BaSnO₃ electrodes for efficient, photostable perovskite solar cells. Science 356, 167-171 (2017).
11 Nie, W. et al. Light-activated photocurrent degradation and self-healing in perovskite solar cells. Nat. Commun. 7, 11574 (2016).
12 Domanski, K. et al. Migration of cations induces reversible performance losses over day/night cycling in perovskite solar cells. Energ. Environ. Sci. 10, 604-613 (2017).
13 Sutton, R. J. et al. Bandgap-tunable cesium lead halide perovskites with high thermal stability for efficient solar cells. Adv. Energy Mater. 6 (2016).
14 Lee, J. W. et al. Formamidinium and cesium hybridization for photo- and moisture-stable perovskite solar cell. Adv. Energy Mater. 5 (2015).
15 Yi, C. et al. Entropic stabilization of mixed A-cation ABX₃ metal halide perovskites for high performance perovskite solar cells. Energ. Environ. Sci. 9, 656-662 (2016).
16 Zhao, J. et al. Strained hybrid perovskite thin films and their impact on the intrinsic stability of perovskite solar cells. Sci. Adv. 3, doi:10.1126/sciadv.aao5616 (2017).
17 Wang, Q. et al. Scaling behavior of moisture-induced grain degradation in polycrystalline hybrid perovskite thin films. Energ. Environ. Sci. 10, 516-522, doi:10.1039/C₆EE02941H (2017).
18 Fan, Z. et al. Layer-by-layer degradation of methylammonium lead tri-iodide perovskite microplates. Joule 1, 548-562, doi:10.1016/j.joule.2017.08.005 (2017).
19 Xiao, Z. et al. Giant switchable photovoltaic effect in organometal trihalide perovskite devices. Nat. Mater. 14, 193 (2015).
20 J. et al. Perovskite—fullerene hybrid materials suppress hysteresis in planar diodes. Nat. Commun. 6, 7081 (2015).
21 Noel, N. K. et al. Enhanced photoluminescence and solar cell performance via Lewis base passivation of organic-inorganic lead halide perovskites. ACS nano 8, 9815-9821 (2014).
22 Zheng, X. et al. Defect passivation in hybrid perovskite solar cells using quaternary ammonium halide anions and cations. Nat. Energy 2, 17102, (2017).
23 Peak, D., Ford, R. G. & Sparks, D. L. An in situ ATR-FTIR investigation of sulfate bonding mechanisms on goethite. J. Colloid Interface Sci. 218, 289-299 (1999).
24 Elzinga, E., Peak, D. & Sparks, D. Spectroscopic studies of Pb (II)-sulfate interactions at the goethite-water interface. Geochim. Cosmochim. Acta 65, 2219-2230 (2001).
25 Yun, J. H. et al. Synergistic enhancement and mechanism study of mechanical and moisture stability of perovskite solar cells introducing polyethylene-imine into the CH₃NH₃PbI₃/HTM interface. J. Mater. Chem. A 3, 22176-22182 (2015).
26 Nocuń-Wczelik, W., Nocuń, M. & Łój, G. The section contains articles of back issues of Materials Science-Poland. Interaction of Pb with hydrating alite paste XPS studies of surface products. Mater. Sci. Poland 27 (2009).
27 Ebitani, K., Konno, H., Tanaka, T. & Hattori, H. In-situ XPS study of zirconium oxide promoted by platinum and sulfate ion. J. Catal. 135, 60-67 (1992).
28 Wang, M. Exploring stability of formamidinium lead trihalide for solar cell application. Sci. Bull. 62, 249-255 (2017).
29 Aristidou, N. et al. Fast oxygen diffusion and iodide defects mediate oxygen-induced degradation of perovskite solar cells. Nat. Commun. 8, 15218 (2017).
30 Rajagopal, A. et al. Overcoming the photovoltage plateau in large bandgap perovskite photovoltaics. Nano Left. 18, 3985-3993 (2018).
31 Xing, J. et al. Ultrafast ion migration in hybrid perovskite polycrystalline thin films under light and suppression in single crystals. Phys. Chem. Chem. Phys. 18, 30484-30490 (2016).
32 Yuan, Y. & Huang, J. Ion migration in organometal trihalide perovskite and its impact on photovoltaic efficiency and stability. Acc. Chem. Res. 49, 286-293 (2016).
33 Yuan, H. et al. Degradation of methylammonium lead iodide perovskite structures through light and electron beam driven ion migration. J. Phys. Chem. L. 7, 561-566, (2016).
34 Shao, Y. et al. Grain boundary dominated ion migration in polycrystalline organic—inorganic halide perovskite films. Energ. Environ. Sci. 9, 1752-1759 (2016).
35 Shao, Y., Xiao, Z., Bi, C., Yuan, Y. & Huang, J. Origin and elimination of photocurrent hysteresis by fullerene passivation in CH₃NH₃PbI₃ planar heterojunction solar cells. Nat. Commun. 5, 5784 (2014).
36 Vorpahl, S. M. et al. Impact of microstructure on local carrier lifetime in perovskite solar cells. Science 348, 683-686 (2015).
37 Yang, W. S. et al. Iodide management in formamidinium-lead-halide—based perovskite layers for efficient solar cells. Science 356, 1376-1379 (2017).
38 Black, L. E. New perspectives on surface passivation: Understanding the Si-Al₂O₃ interface. (Springer, 2016).

### STATEMENTS REGARDING INCORPORATION BY REFERENCE AND VARIATIONS

All references throughout this application, for example patent documents including issued or granted patents or equivalents; patent application publications; and non-patent literature documents or other source material; are hereby incorporated by reference herein in their entireties, as though individually incorporated by reference, to the extent each reference is at least partially not inconsistent with the disclosure in this application (for example, a reference that is partially inconsistent is incorporated by reference except for the partially inconsistent portion of the reference).

The terms and expressions which have been employed herein are used as terms of description and not of limitation, and there is no intention in the use of such terms and expressions of excluding any equivalents of the features shown and described or portions thereof, but it is recognized that various modifications are possible within the scope of the invention claimed. Thus, it should be understood that although the present invention has been specifically disclosed by preferred embodiments, exemplary embodiments and optional features, modification and variation of the concepts herein disclosed may be resorted to by those skilled in the art, and that such modifications and variations are considered to be within the scope of this invention as defined by the appended claims. The specific embodiments provided herein are examples of useful embodiments of the present invention and it will be apparent to one skilled in the art that the present invention may be carried out using a large number of variations of the devices, device components, methods steps set forth in the present description. As will be obvious to one of skill in the art, methods and devices useful for the present methods can include a large number of optional composition and processing elements and steps.

As used herein and in the appended claims, the singular forms “a”, “an”, and “the” include plural reference unless the context clearly dictates otherwise. Thus, for example, reference to “a cell” includes a plurality of such cells and equivalents thereof known to those skilled in the art. As well, the terms “a” (or “an”), “one or more” and “at least one” can be used interchangeably herein. It is also to be noted that the terms “comprising”, “including”, and “having” can be used interchangeably. The expression “of any of claims XX-YY” (wherein XX and YY refer to claim numbers) is intended to provide a multiple dependent claim in the alternative form, and in some embodiments is interchangeable with the expression “as in any one of claims XX-YY.”

When a group of substituents is disclosed herein, it is understood that all individual members of that group and all subgroups, including any isomers, enantiomers, and diastereomers of the group members, are disclosed separately. When a Markush group or other grouping is used herein, all individual members of the group and all combinations and subcombinations possible of the group are intended to be individually included in the disclosure. When a compound is described herein such that a particular isomer, enantiomer or diastereomer of the compound is not specified, for example, in a formula or in a chemical name, that description is intended to include each isomers and enantiomer of the compound described individual or in any combination. Additionally, unless otherwise specified, all isotopic variants of compounds disclosed herein are intended to be encompassed by the disclosure. For example, it will be understood that any one or more hydrogens in a molecule disclosed can be replaced with deuterium or tritium. Isotopic variants of a molecule are generally useful as standards in assays for the molecule and in chemical and biological research related to the molecule or its use. Methods for making such isotopic variants are known in the art. Specific names of compounds are intended to be exemplary, as it is known that one of ordinary skill in the art can name the same compounds differently.

Certain molecules disclosed herein may contain one or more ionizable groups [groups from which a proton can be removed (e.g., —COOH) or added (e.g., amines) or which can be quaternized (e.g., amines)]. All possible ionic forms of such molecules and salts thereof are intended to be included individually in the disclosure herein. With regard to salts of the compounds herein, one of ordinary skill in the art can select from among a wide variety of available counterions those that are appropriate for preparation of salts of this invention for a given application. In specific applications, the selection of a given anion or cation for preparation of a salt may result in increased or decreased solubility of that salt.

Every device, system, formulation, material, combination of components, or method described or exemplified herein can be used to practice the invention, unless otherwise stated.

Whenever a range is given in the specification, for example, a temperature range, a time range, or a composition or concentration range, all intermediate ranges and subranges, as well as all individual values included in the ranges given are intended to be included in the disclosure. It will be understood that any subranges or individual values in a range or subrange that are included in the description herein can be excluded from the claims herein.

All patents and publications mentioned in the specification are indicative of the levels of skill of those skilled in the art to which the invention pertains. References cited herein are incorporated by reference herein in their entirety to indicate the state of the art as of their publication or filing date and it is intended that this information can be employed herein, if needed, to exclude specific embodiments that are in the prior art. For example, when composition of matter is claimed, it should be understood that compounds known and available in the art prior to Applicant's invention, including compounds for which an enabling disclosure is provided in the references cited herein, are not intended to be included in the composition of matter claims herein.

As used herein, “comprising” is synonymous with “including,” “containing,” or “characterized by,” and is inclusive or open-ended and does not exclude additional, unrecited elements or method steps. As used herein, “consisting of” excludes any element, step, or ingredient not specified in the claim element. As used herein, “consisting essentially of” does not exclude materials or steps that do not materially affect the basic and novel characteristics of the claim. In each instance herein any of the terms “comprising”, “consisting essentially of” and “consisting of” may be replaced with either of the other two terms. The invention illustratively described herein suitably may be practiced in the absence of any element or elements, limitation or limitations which is not specifically disclosed herein.

One of ordinary skill in the art will appreciate that starting materials, biological materials, reagents, synthetic methods, purification methods, analytical methods, assay methods, and biological methods other than those specifically exemplified can be employed in the practice of the invention without resort to undue experimentation. All art-known functional equivalents, of any such materials and methods are intended to be included in this invention. The terms and expressions which have been employed are used as terms of description and not of limitation, and there is no intention that in the use of such terms and expressions of excluding any equivalents of the features shown and described or portions thereof, but it is recognized that various modifications are possible within the scope of the invention claimed. Thus, it should be understood that although the present invention has been specifically disclosed by preferred embodiments and optional features, modification and variation of the concepts herein disclosed may be resorted to by those skilled in the art, and that such modifications and variations are considered to be within the scope of this invention as defined by the appended claims.

We claim:

1. An electronic device comprising:
a positive electrode;
a negative electrode;
a first layer disposed between said positive electrode and said negative electrode, said first layer comprising a perovskite material; and
a coating layer disposed on a surface of said first layer;
wherein said coating layer comprises a coating oxysalt.

2. The device of claim 1, wherein said first layer is an active layer of said electronic device.

3. The device of claim 1, wherein said coating oxysalt is characterized by a chemical formula comprising a metal element.

4. The device of claim 3, wherein said perovskite material is characterized by a chemical formula comprising said metal element.

5. The device of claim 1, wherein said coating oxysalt is characterized by a chemical formula comprising an inorganic anion.

6. The device of claim 1, wherein said coating oxysalt is characterized by a chemical formula comprising at least one anion selected from the group consisting of SO₄² , SO₃² , SO₆⁶ , PO₄⁻³ , PO₅^{5 -}, PO₃ , CO₃² , CO₄⁴ , C₂O₄^{2 -},OH , ClO⁻, ClO₂⁻, ClO₃⁻, ClO₄⁻, NO₂⁻, NO₃⁻, BO₂⁻, BO3³⁻, AsO₄³⁻, MnO₄⁻, SeO₄²⁻, TeO₆⁶⁻, BrO⁻, BrO4⁻, IO₋, IO₆⁶⁻, SiO₄⁴⁻, Cr₂O₇²⁻, and any combination thereof.

7. The device of claim 1, wherein said coating oxysalt is characterized by a chemical formula comprising at least one cation selected from the group consisting of Pb, Sn, Cd, Bi, Sb, Fe, Ge, Mn, Mo, Ta, Ag, and any combination thereof.

8. The device of claim 1, wherein said coating oxysalt comprises a compound selected from the group consisting of PbSO₄, PbSO₃, Pb₃SO₆, Pb₃(PO₄)₂, Pb₅(PO₅)₂, Pb(PO₃)₂, PbCO₃, Pb₂CO₄, PbC₂₀₄, Pb(OH)₂, Pb(CIO)₂, Pb(C₁₀₂)₂, Pb(C₁₀₃)₂, Pb(C₁₀₄)₂, Pb(NO₂)₂, Pb(NO₃)₂, Pb(B02)₂, Pb₃(BO₃)₂, Pb₃(As04)₂, Pb(MnO₄)₂, PbSeO₄, Pb₃TeO₆, Pb(BrO)₂, Pb(BrO₄)₂, Pb(IO)₂, Pb(IO₄)₂, Pb₃IO_{6 ,}Pb₂SiO₄, PbCr2O₇, and any combination thereof.

9. The device of claim 1, wherein said perovskite material is an inorganic perovskite material, and an organic-inorganic perovskite material, or a combination thereof.

10. The device of claim 1, wherein the perovskite material is characterized by a chemical formula comprising at least two chemical species selected from the group consisting of Pb, Sn, Sb, Fe, Ge, Mn, Mo, Ta, Ag, Na, K, Ru, Cs, formamidinium (“FA”), methylammonium (“MA”), ethylammonium, propylammonium, butylammonium, amylammonium, hexylammonium, heptylammonium, octylammonium, oleylammonium, formamidinium, dodecylammonium, phenylethylammonium, benzylammonium, ethylenediammonium, tetramethylammonium, tetraethylammonium, tetrabutylammonium, hexadecyl trimethyl ammonium, and ethanediammonium, and at least one chemical species selected from the group consisting of I, Br, CI, F, COO, BF₃ and SCN.

11. The device of claim 1, wherein said perovskite material is characterized by a chemical formula comprising Pb and wherein said coating oxysalt is characterized by a chemical formula comprising Pb.

12. The device of claim 1, wherein said first layer is a thin film characterized by a thickness selected from the range of 2 nm to 10 μm.

13. The device of claim 1, wherein said electronic device is a photoactive device.

14. The device of claim 1, wherein said electronic device is selected from the group consisting of a solar cell, a light emitting diode, a photodiode, a photoelectrochemical cell, a photoresistor, phototransistor, photomultiplier, photoelectric cell, an electrochromic cell, a radiation detector, a X-ray detector, and a gamma-ray detector.

15. The device of claim 1, wherein said coating layer is a semiconductor characterized by a band gap selected from the range of 1.6 eV to 8.5 eV.

16. The device of claim 1, wherein said coating oxysalt is characterized by a solubility in water of less than 1 g per 100 mL of water at 20° C.

17. The device of claim 16, wherein said coating oxysalt is characterized by a solubility in water of less than 0.02 g per 100 mL of water at 20° C.

18. The device of claim 1, wherein said coating oxysalt is formed via a chemical reaction of a precursor oxysalt with said perovskite material.

19. The device of claim 1, wherein an absorbance loss at 740 nm of said perovskite material in said first layer is less than 20% after at least 500 hours of exposure to ambient air under an illumination equivalent to 1 sun.

20. A perovskite material, said perovskite material comprising:
a coating layer on at least a portion of a surface of said perovskite material;
wherein said coating layer comprises a coating oxysalt.

21. The perovskite material of claim 20, wherein said coating oxysalt is characterized by a chemical formula comprising a metal element and wherein said perovskite material is characterized by a chemical formula comprising said metal element.

22. The perovskite material of claim 20, wherein said coating oxysalt is characterized by a chemical formula comprising an inorganic anion.

23. The perovskite material of claim 20 wherein said perovskite material is characterized by a chemical formula comprising Pb and wherein said coating oxysalt is characterized by a chemical formula comprising Pb.

24. The perovskite material of claim 20, said perovskite material is characterized by a chemical formula comprising at least two chemical species selected from the group consisting of Pb, Cs, Sn, Sb, Fe, Ge, Mn, Mo, Ta, Ag, Na, K, Ru, Cs, formamidinium (“FA”), methylammonium (“MA”), ethylammonium, propylammonium, butylammonium, amylammonium, hexylammonium, heptylammonium, octylammonium, oleylammonium, formamidinium, dodecylammonium, phenylethylammonium, benzylammonium, ethylenediammonium, tetramethylammonium, tetraethylammonium, tetrabutylammonium, hexadecyl trimethyl ammonium, and ethanediammonium, and at least one chemical species selected from the group consisting of I, Br, CI, F, COO, BF₃, and SCN.

25. The perovskite material of claim 20, wherein said coating oxysalt is characterized by a solubility in water of less than 1 g per 100 mL of water at 20° C.

26. The perovskite material of claim 20, wherein said coating layer is formed via a chemical reaction of a precursor oxysalt with said perovskite material.

27. The perovskite material of claim 20, wherein an absorbance loss at 740 nm of said perovskite material is less than 20% after at least 500 hours of exposure to ambient air under an illumination equivalent to 1 sun.

28. The perovskite material of claim 20, wherein said perovskite material is substantially black after at least 1 second of immersion in liquid water.

29. The perovskite material of claim 20, wherein said perovskite material is a single crystal, a thin film, a nanomaterial, or a combination of these.

30. A method for forming a coating layer on a surface of a perovskite material, said method comprising steps of:
exposing said surface to a fluid having a precursor oxysalt dissolved therein such that said coating layer forms on said surface via a chemical reaction between said perovskite material and said precursor oxysalt;
wherein said coating layer comprises a coating oxysalt.

31. The method of claim 30, wherein said fluid is a liquid solution comprising a solvent and said precursor oxysalt.

32. The method of claim 30, wherein said solvent is an orthogonal solvent.

33. The method of claim 30, wherein said solvent comprises a compound selected from the group consisting of isopropanol, toluene, chlorobenzene, benzene, chloroform, dichloromethane, trichloromethane, ethanol, methanol, butanol, pentanol, hexanol, heptanol, ethyl acetate, methyl acetate, ethyl formate, methyl formate, 1,2-dichlorobenzene, 1,4-dioxane, butanone, carbon disulfide, carbon tetrachloride, cyclohexanone, diglyme, heptane, p-xylene, tetrahydrofuran, and any combination thereof.

34. The method of claim 30, wherein said chemical reaction occurs for a time selected from the range of 0.001 seconds to 1800 seconds.

35. The method of claim 30, wherein a temperature of said fluid is selected from the range of -40° C. to 100° C. during said step of exposing.

36. The method of claim 30, wherein a temperature of said perovskite material is selected from the range of 0° C. to 200° C. during said step of exposing.

37. The method of claim 30, wherein said coating oxysalt is characterized by a chemical formula comprising a metal element and wherein said perovskite material is characterized by a chemical formula comprising said metal element.

38. The method of claim 30, wherein said coating oxysalt is characterized by a chemical formula comprising an inorganic anion.

39. The method of claim 30, wherein said perovskite material is characterized by a chemical formula comprising Pb and wherein said coating oxysalt is characterized by a chemical formula comprising Pb.

40. The method of claim 30, said perovskite material is characterized by a chemical formula comprising at least two chemical species selected from the group consisting of Pb, Sn, Sb, Fe, Ge, Mn, Mo, Ta, Ag, Na, K, Ru, Cs, formamidinium (“FA”), methylammonium (“MA”), methylammonium, ethylammonium, propylammonium, butylammonium, amylammonium, hexylammonium, heptylammonium, octylammonium, oleylammonium, formamidinium, dodecylammonium, phenylethylammonium, benzylammonium, ethylenediammonium, tetramethylammonium, tetraethylammonium, tetrabutylammonium, hexadecyl trimethyl ammonium, ethanediammonium, and at least one chemical species selected from the group consisting of I, Br, CI, F, COO, BF₃, and SCN.

41. The method of claim 30, wherein said coating oxysalt is characterized by a solubility in water of less than 1 g per 100 mL of water at 20° C.

42. The method of claim 30, wherein an absorbance loss at 740 nm of said perovskite material is less than 20% after at least 500 hours of exposure to ambient air under an illumination equivalent to 1 sun.

43. The method of claim 30, wherein said perovskite material is substantially black after at least 1 second of immersion in liquid water.

44. The method of claim 30, wherein said perovskite material is a single crystal, a thin film, a nanomaterial, or a combination of these.
